(19) United States
(12) Patent Application Publication
(10) Pub. No.: US 2024/0389388 A1
(43) Pub. Date: Nov. 21, 2024

(54) DISPLAY DEVICE

(71) Applicant: Sharp Display Technology Corporation, Kameyama City, Mie (JP)

(72) Inventor: Shogo SUZUKI, Kameyama City, Mie (JP)

(21) Appl. No.: 18/688,763

(22) PCT Filed: Nov. 15, 2021
(86) PCT No.: PCT/JP2021/041887

§ 371 Date: Mar. 2, 2024

(51) Int. Cl. H10K 59/121; H10K 59/131

(52) U.S. Cl. CPC H10K 59/1213; H10K 59/131

(57) ABSTRACT

An organic EL display device includes: a plurality of organic EL elements arranged both in a row direction and in a column direction; and a plurality of TFTs configured to respectively control emission of light by the plurality of organic EL elements. The emission of light by the organic EL elements is controlled through operation of the TFTs individually for the plurality of organic EL elements arranged in the row direction. A display area where an image is displayed includes: a plurality of first areas capable of emitting light owing to the organic EL elements; and a plurality of second areas capable of transmitting light that comes from behind. The first areas and the second areas are alternately provided in the row direction and in the column direction.

### TECHNICAL FIELD

The present disclosure relates to display devices.

### BACKGROUND ART

Display devices have been known that function as a see-through display device that allows the user to see the background, for example, the scenery behind the display device while producing an image display thereon for viewing by the user. As such a display device, for example, Patent Literature 1 discloses an organic light-emitting display device including a plurality of pixels each having a non-transparent region and a transparent region. This organic light-emitting display device has a display area in which the non-transparent regions emit light. Then, the display area and the transparent regions are separated by conduction lines. This particular structure ensures wide transparent regions for improved light transmission, thereby minimizing image distortion.

### CITATION LIST

### Patent Literature

Patent Literature 1: Japanese Unexamined Patent Application Publication No. 2012-134118

### SUMMARY OF INVENTION

### Technical Problem

In the organic light-emitting display device disclosed in Patent Literature 1, the transparent regions are aligned linearly in the direction in which scan lines are extended. Therefore, in the display unit, the background that the user can see through the display area sometimes appears like horizontal stripes on the displayed image produced by the light emitted in the display area. These stripes become increasingly visible with larger pixels. When the background appears like horizontal stripes on the display screen of the display device, the background as visually recognized through the display loses its natural transparency, which degrades the display quality of the see-through display device.

It is an object of the present disclosure to restrain, in a display device that functions as a see-through display device, the background that the user can see through the display area from appearing like stripes on the displayed image and to at the same time achieve a high background transmittance.

### Solution to Problem

The technique of the present disclosure is directed to a display device. A display device in accordance with the technique of the present disclosure includes: a plurality of light-emitting elements arranged both in a first direction and in a second direction, the first direction and the second direction being orthogonal to each other; and a plurality of active elements configured to respectively control emission of light by the plurality of light-emitting elements, the display device displaying an image by controlling the emission of light by the plurality of light-emitting elements through operation of the plurality of active elements individually for the plurality of light-emitting elements arranged in the first direction or individually for the plurality of light-emitting elements arranged in the second direction. In this display device, a display area where an image is displayed includes: a plurality of first areas capable of emitting light owing to the plurality of light-emitting elements; and a plurality of second areas capable of transmitting light that comes from behind. The plurality of first areas and the plurality of second areas are alternately provided in the first direction and in the second direction.

### Advantageous Effects of Invention

The technique of the present disclosure can restrain, in a display device that functions as a see-through display device, the background that the user can see through the display area from appearing like stripes on the displayed image and to at the same time achieve a high background transmittance.

### BRIEF DESCRIPTION OF DRAWINGS

FIG. 1 is a schematic plan view of an example of a structure of an organic EL display device in accordance with Embodiment 1.

FIG. 2 is a cross-sectional view of the organic EL display device taken along line A-A shown in FIG. 1.

FIG. 3 is a schematic illustration of an example of how the image displayed by the organic EL display device in accordance with Embodiment 1 and the background visible through the display screen appear.

FIG. 4 is a plan view of an example of a structure of a display area of the organic EL display device in accordance with Embodiment 1.

FIG. 5 is a plan view of an example of a structure of a common electrode of the organic EL display device in accordance with Embodiment 1.

FIG. 6 is a plan view of an example of a structure of first areas and second areas of the organic EL display device in accordance with Embodiment 1.

FIG. 7 is a cross-sectional view of the first areas taken along line B-B shown in FIG. 6.

FIG. 8 is a cross-sectional view of the first areas taken along line C-C shown in FIG. 6.

FIG. 9 is a cross-sectional view of the second areas taken along line D-D shown in FIG. 6.

FIG. 10 is a cross-sectional view of the second areas taken along line E-E shown in FIG. 6.

FIG. 11 is a cross-sectional view of an example of a layered structure of an organic EL layer in accordance with Embodiment 1.

FIG. 12 is an equivalent circuit diagram of an example of a pixel circuit in accordance with Embodiment 1.

FIG. 13 is a plan view of an example of a structure of first areas and second areas of an organic EL display device in accordance with a first variation example of Embodiment 1.

FIG. 14 is a cross-sectional view of the first areas taken along line F-F shown in FIG. 13.

FIG. 15 is a cross-sectional view of the first areas taken along line G-G shown in FIG. 13.

FIG. 16 is a cross-sectional view of the second areas taken along line H-H shown in FIG. 13.

FIG. 17 is a cross-sectional view of the second areas taken along line I-I shown in FIG. 13.

FIG. 18 is a plan view of an example of a structure of first areas and second areas of an organic EL display device in accordance with a second variation example of Embodiment 1.

FIG. 19 is a cross-sectional view of the first areas taken along line J-J shown in FIG. 18.

FIG. 20 is a cross-sectional view of the first areas taken along line K-K shown in FIG. 18.

FIG. 21 is a cross-sectional view of the second areas taken along line L-L shown in FIG. 18.

FIG. 22 is a cross-sectional view of the second areas taken along line M-M shown in FIG. 18.

FIG. 23 is a plan view of an example of a structure of a display area of an organic EL display device in accordance with a third variation example of Embodiment 1.

FIG. 24 is a plan view of an example of a structure of a display area of an organic EL display device in accordance with a fourth variation example of Embodiment 1.

FIG. 25 is a plan view of an example of a structure of a display area of an organic EL display device in accordance with a fifth variation example of Embodiment 1.

FIG. 26 is a plan view of an example of a structure of a display area of an organic EL display device in accordance with a sixth variation example of Embodiment 1.

FIG. 27 is an equivalent circuit diagram of an example of a pixel circuit in accordance with a seventh variation example of Embodiment 1.

FIG. 28 is a plan view of an example of a structure of a display area of an organic EL display device in accordance with Embodiment 2.

FIG. 29 is a plan view of an example of a structure of first areas and second areas of the organic EL display device in accordance with Embodiment 2.

FIG. 30 is a cross-sectional view of the first areas taken along line N-N shown in FIG. 29.

FIG. 31 is a cross-sectional view of the first areas taken along line O-O shown in FIG. 29.

FIG. 32 is a cross-sectional view of the second areas taken along line P-P shown in FIG. 29.

FIG. 33 is a cross-sectional view of the second areas taken along line Q-Q shown in FIG. 29.

FIG. 34 is an equivalent circuit diagram of an example of a pixel circuit in accordance with Embodiment 2.

FIG. 35 is a plan view of an example of a structure of first areas and second areas of an organic EL display device in accordance with a first variation example of Embodiment 2.

FIG. 36 is a cross-sectional view of the first areas taken along line R-R shown in FIG. 35.

FIG. 37 is a cross-sectional view of the first areas taken along line S-S shown in FIG. 35.

FIG. 38 is a cross-sectional view of the second areas taken along line T-T shown in FIG. 35.

FIG. 39 is a cross-sectional view of the second areas taken along line U-U shown in FIG. 35.

FIG. 40 is a plan view of an example of a structure of first areas and second areas of an organic EL display device in accordance with a second variation example of Embodiment 2.

FIG. 41 is a cross-sectional view of the first areas taken along line V-V shown in FIG. 40.

FIG. 42 is a cross-sectional view of the first areas taken along line W-W shown in FIG. 40.

FIG. 43 is a cross-sectional view of the second areas taken along line X-X shown in FIG. 40.

FIG. 44 is a cross-sectional view of the second areas taken along line Y-Y shown in FIG. 40.

FIG. 45 is an equivalent circuit diagram of an example of a pixel circuit in accordance with a third variation example of Embodiment 2.

FIG. 46 is a plan view of an example of a structure of a display area of an organic EL display device in accordance with Embodiment 3.

FIG. 47 is a plan view of an example of a structure of first areas and second areas of the organic EL display device in accordance with Embodiment 3.

FIG. 48 is a cross-sectional view of the first areas taken along line Z-Z shown in FIG. 47.

FIG. 49 is a cross-sectional view of the first areas taken along line AA-AA shown in FIG. 47.

FIG. 50 is a cross-sectional view of the second areas taken along line AB-AB shown in FIG. 47.

FIG. 51 is an equivalent circuit diagram of an example of a pixel circuit in accordance with Embodiment 3.

FIG. 52 is a plan view of an example of a structure of a display area of an organic EL display device in accordance with a first variation example of Embodiment 3.

FIG. 53 is a plan view of an example of a structure of first areas and second areas of the organic EL display device in accordance with the first variation example of Embodiment 3.

FIG. 54 is a cross-sectional view of the first areas taken along line AC-AC shown in FIG. 53.

FIG. 55 is a cross-sectional view of the second areas taken along line AD-AD shown in FIG. 54.

FIG. 56 is a plan view of an example of a structure of a display area of the organic EL display device in accordance with the first variation example of Embodiment 3.

FIG. 57 is an equivalent circuit diagram of an example of a pixel circuit in accordance with a second variation example of Embodiment 3.

### DESCRIPTION OF EMBODIMENTS

The following will describe illustrative embodiments in detail with reference to drawings. The embodiments below will describe an organic electroluminescence (hereinafter, “EL”) display device as an example of a display device in accordance with the technique of the present disclosure. Note that the drawings have been prepared to illustrate the concepts of the technique of the present disclosure. Therefore, the drawings may exaggerate or simplify dimensions, ratios, or numbers to facilitate the understanding of the technique of the present disclosure.

Throughout the following embodiments, the “row direction” refers to the horizontal direction on the display screen of the display device and coincides with a first direction. The “column direction” refers to the vertical direction on the display screen of the display device and coincides with a second direction. A row of structural members such as subpixels refers to a widthwise string of the structural members aligned in the row direction. A column of structural members such as subpixels refers to a lengthwise string of the structural members aligned in the column direction.

Throughout the following embodiments, a structural member such as a film, a layer, or an element may be described as being disposed, provided, or formed on another structural member such as a film, a layer, or an element not only when the former structural member sits directly on the latter structural member, but also when these structural members are separated by another, intervening structural member such as a film, a layer, or an element.

In addition, throughout the following embodiments, a structural member such as a film, a layer, or an element may be described as being connected to another structural member such as a film, a layer, or an element when these structural members are electrically connected together unless otherwise mentioned explicitly. This language may be used not only when the structural members are directly connected, but also when the structural members are indirectly connected via yet another structural member such as a film, a layer, or an element, without departing from the scope of the technique of the present disclosure. The language may be used also when a structural member is integrated with another additional structural member, in other words, a structural member partially constitutes another structural member.

In addition, throughout the following embodiments, a structural member such as a film, a layer, or an element may be described as being in the same layer as another structural member such as a film, a layer, or an element when these structural members are formed in the same process. A structural member may be described as underlying/being below another structural member when the former structural member is formed in an earlier process or step than the latter structural member. A structural member may be described as overlying/being on/being above another structural member when the former structural member is formed in a later process or step than the other structural member.

In addition, throughout the following embodiments, a structural member such as a film, a layer, or an element may be described as being identical or equivalent to another structural member such as a film, a layer, or an element not only when these structural members are completely identical or equivalent, but also when the structural members are substantially identical or equivalent where they may vary within the range of manufacturing variations and tolerances.

In addition, in the following embodiments, the ordinal numbers, “first,” “second,” “third,” and the like, are used to distinguish between the structural members to which the numbers are assigned and do not limit their number or establish any order between them.

### Embodiment 1

An organic EL display device 1 is a display device functioning as a see-through display device that renders the background behind the display device visible to the user. The background that is rendered visible to the user by the organic EL display device 1 is, for example, particular objects, images displayed by another display panel, or sceneries.

### Structure of Organic EL Display Device

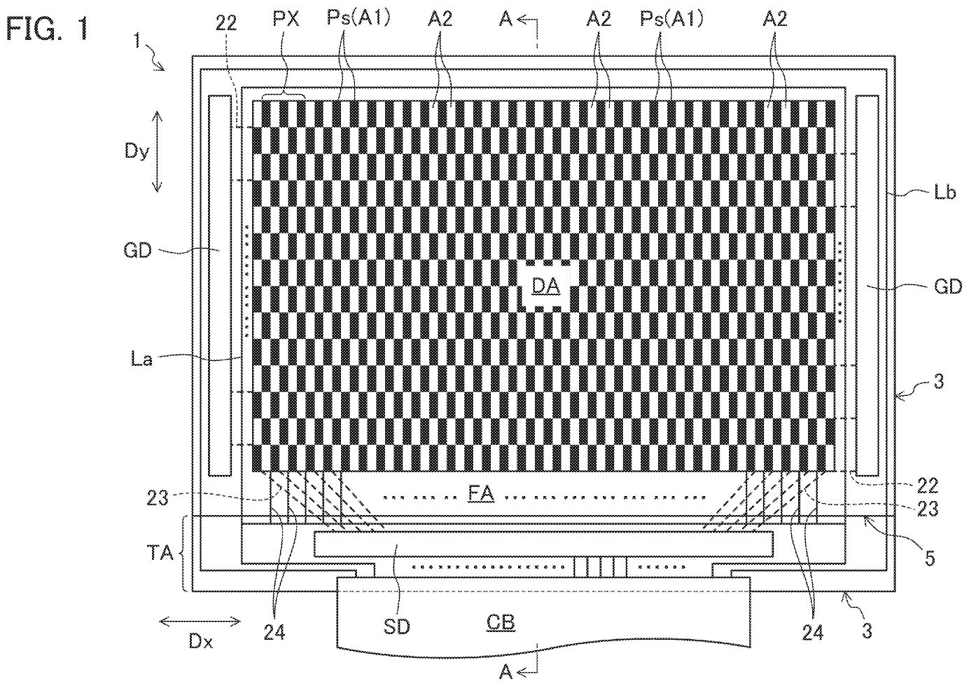

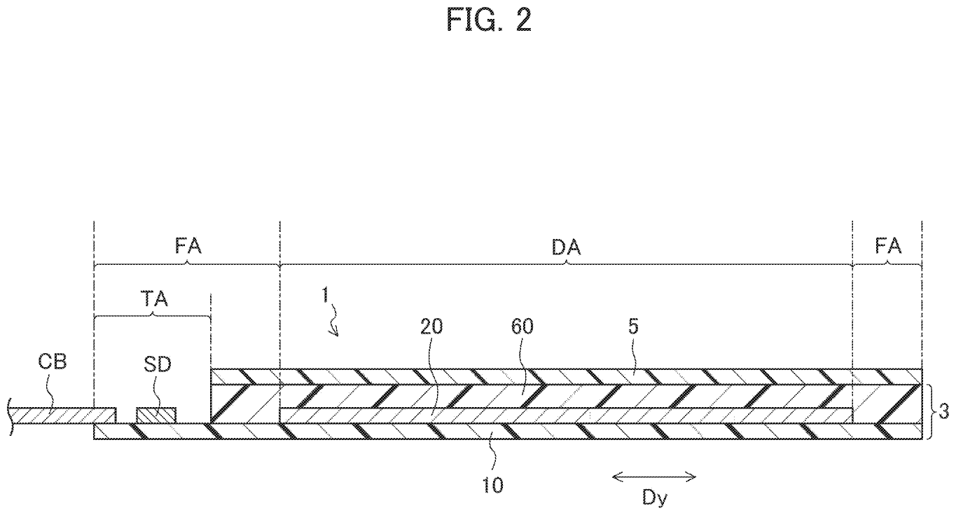

Referring to FIGS. 1 and 2, the organic EL display device 1 includes a display area DA and a frame area FA.

The display area DA is a region where images are displayed and is a part of a display screen. The display area DA is shaped like a rectangle. Although this embodiment describes, by way of example, the display region DA as having a rectangular shape, the display region DA may have a generally rectangular shape, such as a shape with at least one of the sides being arc-shaped, a shape with at least one of the corners being arc-shaped, or a shape with at least one of the sides being cut partly.

The frame area FA is a region where no images are displayed and is a part of a non-display section that is not the display screen. The frame area FA is shaped like a rectangular frame. A portion that constitutes a side of the frame area FA (the bottom side in FIG. 1) constitutes a terminal region TA. The terminal region TA is provided in a region jutting out of an opposite substrate 5 of an array substrate 3 in a plan view. To the terminal region TA is connected a wiring board CB, for example, an FPC (flexible printed circuit) for connecting to an external circuit such as a display control circuit.

A source driver SD is mounted as an IC (integrated circuit) chip between the display area DA and a portion to which the wiring board CB is connected in the terminal region TA. A gate driver GD is monolithically provided in each portion that is at least a part of the sides adjacent to that side of the frame area FA along which the terminal region TA is provided (the left and right sides in FIG. 1).

A first frame line La and a second frame line Lb are also provided in the frame area FA. The first frame line La and the second frame line Lb are provided on the array substrate 3 so as to surround the display area DA and extends to the terminal region TA. A high-level power supply voltage (BLVDD) is supplied from the terminal region TA to the first frame line La via the wiring board CB. A low-level power supply voltage (ELVSS) is supplied from the terminal region TA to the second frame line Lb via the wiring board CB.

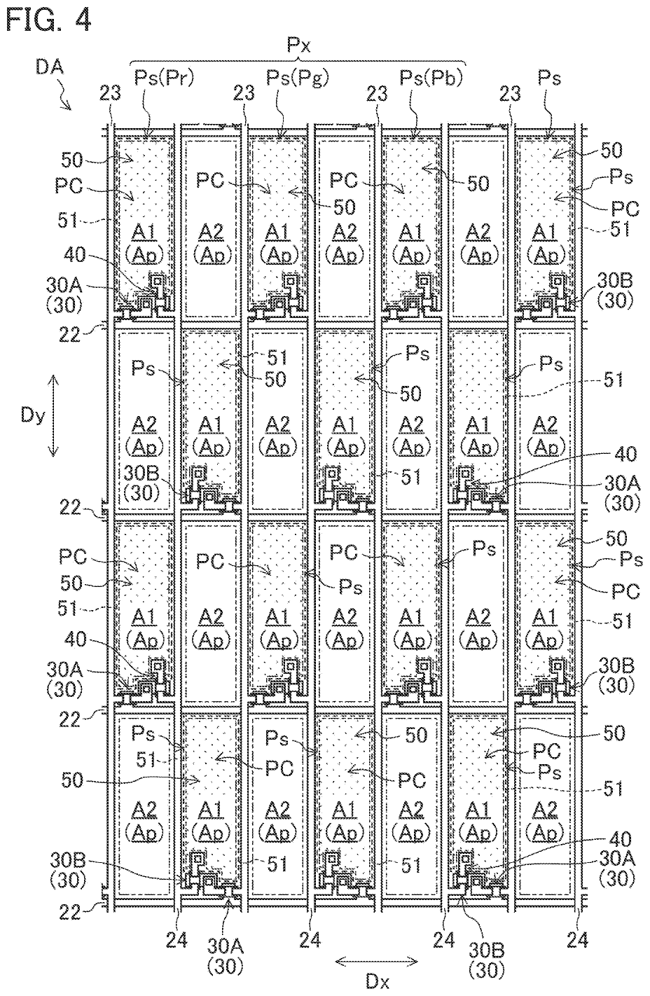

As further shown in FIG. 4, the display area DA includes a plurality of pixels PX. The plurality of pixels PX include three subpixels Ps. The three subpixels Ps are a red light-emitting subpixel Pr, a green light-emitting subpixel Pg, and a blue light-emitting subpixel Pb. The 3-color subpixels Ps that form each pixel PX of the present example are adjacent to each other in the row direction Dx.

The display area DA is structured like a matrix of subpixels Ps parts of which are removed. The display area DA includes a plurality of first areas A1 (represented by hatching in FIG. 4) and a plurality of second areas A2. The first area A1 is a light-emitting region capable of emitting light owing to an organic EL element 50. The second area A2 is a see-through region capable of transmitting light from behind the organic EL display device 1 (rear side) to the front side.

The plurality of first areas A1 and the plurality of second areas A2 are mixed in the display area DA. The plurality of first areas A1 are arranged in a staggered manner. The plurality of second areas A2 are arranged in a staggered manner so as to be positioned between adjacent first areas A1. Hence, the first areas A1 and the second areas A2 are arranged in a checkered pattern. The first areas A1 and the second areas A2 are alternately provided when viewed in the row direction Dx and alternately provided when viewed in the column direction Dy. The first areas A1 are arranged continuously in an oblique direction with respect to the row direction Dx and the column direction Dy. Likewise, the second areas A2 are arranged continuously in an oblique direction with respect to the row direction Dx and the column direction Dy.

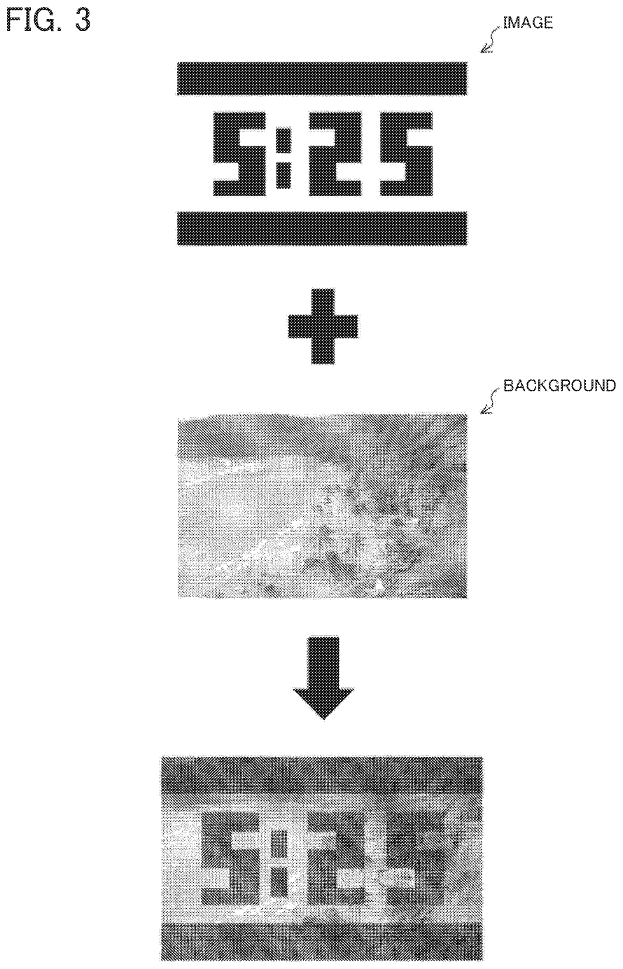

As shown in an example in FIG. 3, the organic EL display device 1 displays an image (still or moving image) in the display area DA and allows the user to observe the background behind the device 1 through the displayed image across the entire display area DA. Note that some of the second areas A2 may be non-see-through regions that block light coming from the rear side of the organic EL display device 1 so as not to allow the user to visually recognized the background behind the device 1.

The organic EL display device 1 operates by an active matrix driving scheme where images are displayed by individually controlling the emission of light by the individual subpixels Ps. Referring to FIG. 2, the organic EL display device 1 includes the array substrate 3 and the opposite substrate 5. The array substrate 3 includes a base substrate 10, an element layer 20, and a sealing film 60. The opposite substrate 5 is attached to the sealing film 60 opposite the array substrate 3.

### Base Substrate

The base substrate 10 is a substrate that provides a base for the organic EL display device 1. The base substrate 10 is composed of an organic resin material such as a polyimide resin, a polyamide resin, or an epoxy resin. The base substrate 10 may have a layered structure including a stack of an inorganic insulating layer composed of an inorganic insulating material such as a silicon oxide, a silicon nitride, or a silicon oxynitride and a resin layer composed of the above-described organic resin material.

### Element Layer

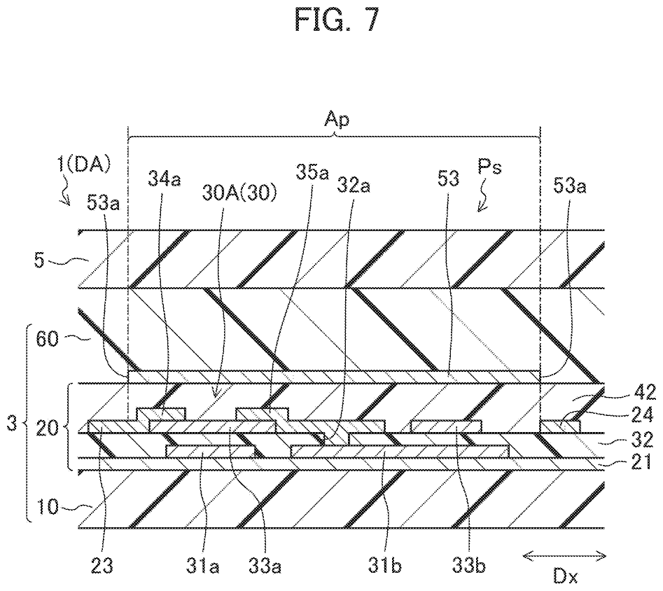

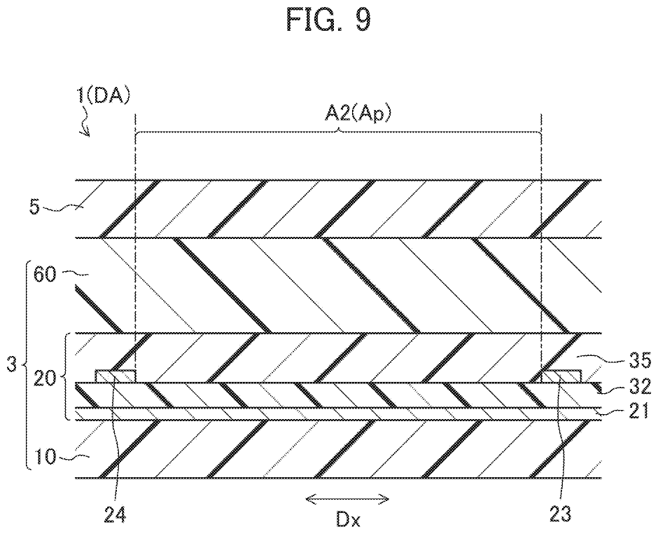

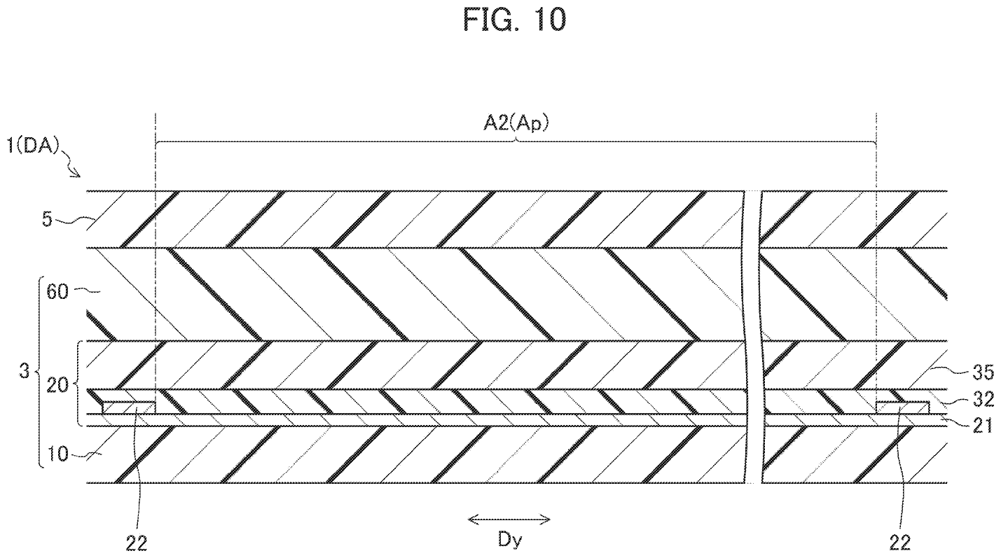

Referring to FIGS. 7 to 10, the element layer 20 includes a base coat film 21, a plurality of gate lines 22, a plurality of source lines 23, a plurality of power supply lines 24, a plurality of thin film transistors (hereinafter, “TFTs”) 30, a plurality of capacitors 40, and the plurality of organic EL elements 50. The base coat film 21 is provided across the entire surface of the base substrate 10. The plurality of TFTs 30, the plurality of capacitors 40, and the plurality of organic EL elements 50 are provided on the base coat film 21.

Each gate line 22 is a wire for transferring a gate signal. The gate line 22 is an example of a third wiring line. Referring to FIGS. 4 to 6, the plurality of gate lines 22 are provided in the display area DA and extend parallel to each other in the row direction Dx between rows of adjacent subpixels Ps. The plurality of gate lines 22 are arranged at intervals from each other when viewed in the column direction Dy. One gate line 22 is provided for each row of subpixels Ps. Each gate line 22 is connected to each pixel circuit PC for the plurality of subpixels Ps that are arranged in the row direction Dx. Each gate line 22 is connected to the gate driver GD.

Each source line 23 is a wire for transferring a source signal. The source line 23 is an example of a first wiring line. The plurality of source lines 23 are provided in the display area DA and extend parallel to each other in the column direction Dy in the gaps between columns of adjacent subpixels Ps. The plurality of source lines 23 are arranged at intervals from each other when viewed in the row direction Dx. One source line 23 is provided for every two columns of subpixels Ps. Each source line 23 is connected to each pixel circuit PC for the plurality of subpixels Ps that are arranged in the column direction Dy. Each source line 23 is connected to the source driver SD.

Each power supply line 24 is a wire for applying a prescribed high-level power supply voltage (ELVDD). The power supply line 24 is an example of a second wiring line. The plurality of power supply lines 24 are provided in the display area DA and extend parallel to each other in the column direction Dy in the gaps between columns of adjacent subpixels Ps. The plurality of power supply lines 24 are arranged at intervals from each other when viewed in the row direction Dx. One power supply line 24 is provided for every two columns of subpixels Ps. Each power supply line 24 is connected to each pixel circuit PC for the plurality of subpixels Ps that are arranged in the column direction Dy. Each power supply line 24 is connected to the first frame line La.

The source lines 23 and the power supply lines 24 are alternately provided when viewed in the row direction Dx so as to sandwich the pixel circuits PC therebetween. Of the gaps between columns of adjacent subpixels Ps, the source lines 23 are provided in those gaps where no power supply line 24 is disposed, and the power supply lines 24 are provided in those gaps where no the source line 23 is disposed. Each source line 23 is used commonly by each pixel circuit PC provided for two columns of subpixels Ps that are adjacent to that source line 23. Each power supply line 24 is used commonly by each pixel circuit PC provided for two columns of subpixels Ps that are adjacent to that power supply line 24.

The source lines 23, the power supply lines 24, and the gate lines 22 intersect with each other via a first insulating film 32. The gate lines 22, the source lines 23, and the power supply lines 24 extend in the display area DA so as to form a lattice in a plan view as a whole. In the display area DA, a plurality of compartmental regions Ap are provided that are compartmentalized by the gate lines 22, the source lines 23, and the power supply lines 24. The plurality of compartmental regions Ap form a matrix. The plurality of compartmental regions Ap have equal areas. The first areas A1 and the second areas A2 are specified in different compartmental regions Ap.

The first areas A1 and the second areas A2 in the present example are each provided so as to correspond one-to-one to the compartmental regions Ap. One first area A1 is specified in prescribed, every two compartmental regions Ap both when viewed in the row direction Dx and when viewed in the column direction Dy. The first area A1 is specified across the prescribed, almost entire compartmental regions Ap. One second area A2 is specified in prescribed, every two compartmental regions Ap other than the first areas A1 both when viewed in the row direction Dx and when viewed in the column direction Dy. The second areas A2 are specified across those prescribed, almost entire compartmental regions Ap in which no first areas A1 are specified.

One of the two compartmental regions Ap that are adjacent in the row direction Dx constitutes the first area A1, whereas the other one of these two compartmental regions Ap constitutes the second area A2. Likewise, one of the two compartmental regions Ap that are adjacent in the column direction Dy constitutes the first area A1, whereas the other one of these two compartmental regions Ap constitutes the second area A2. In the present example, the second area A2 is larger in area than the first area A1 by as much as a first TFT 30A, a second TFT 30B, and the capacitor 40 which are provided in the compartmental regions Ap in which the first areas A1 are specified.

The plurality of TFTs 30 respectively control the emission of light by the plurality of organic EL elements 50. The TFT 30 is an example of an active element. The plurality of TFTs 30 include the plurality of first TFTs 30A and the plurality of second TFTs 30B. Each subpixel Ps includes one of the first TFTs 30A and one of the second TFTs 30B. The first TFTs 30A and the second TFTs 30B of the present example are provided in the compartmental regions Ap in which the first areas A1 are specified, but not in the compartmental regions Ap in which the second area A2 is specified.

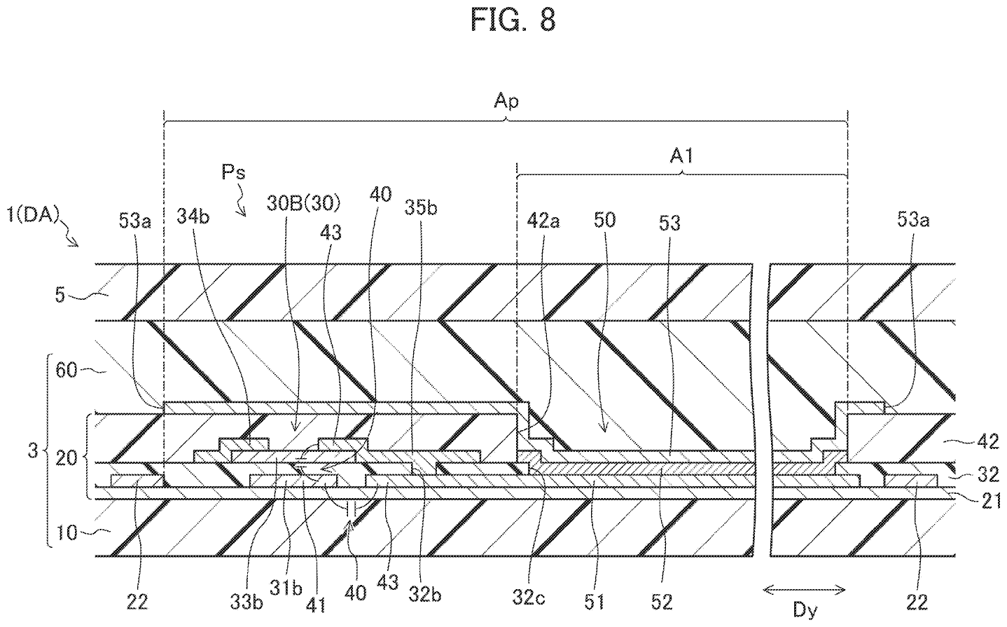

As shown in FIGS. 7 and 8, the first TFTs 30A and the second TFTs 30B of the present example all have a bottom-gate structure. The first TFTs 30A and the second TFTs 30B each include a gate electrode 31a, 31b, the first insulating film 32, a semiconductor layer 33a, 33b, a first terminal electrode 34a, 34b, and a second terminal electrode 35a, 35b.

The gate electrodes 31a, 31b are provided on the base coat film 21. The first insulating film 32 is provided across the almost entire array substrate 3 so as to cover the gate lines 22 and the gate electrodes 31a, 31b. The semiconductor layers 33a, 33b are provided so as to overlap the gate electrodes 31a, 31b via the first insulating film 32.

The first terminal electrodes 34a, 34b and the second terminal electrodes 35a, 35b are positioned in separate locations on the first insulating film 32. The first terminal electrodes 34a, 34b and the second terminal electrodes 35a, 35b are connected overlapping mutually different portions (conduction regions) in locations sandwiching a region (intrinsic region) of the semiconductor layers 33a, 33b that overlaps the gate electrodes 31a, 31b.

The gate electrode 31a of the first TFT 30A is formed integral to the associated one of the gate lines 22. The first terminal electrode 34a of the first TFT 30A is formed integral to the associated one of the source lines 23. The first terminal electrode 34a of each first TFT 30A provided for two columns of adjacent subpixels Ps via the source line 23 is formed integral to the common source line 23. The second terminal electrode 35a of the first TFT 30A is connected to the gate electrode 31b of the second TFT 30B via a contact hole 32a formed in the first insulating film 32.

The first terminal electrode 34b of the second TFT 30B is formed integral to the associated one of the power supply lines 24. The first terminal electrode 34b of each second TFT 30B provided for two columns of adjacent subpixels Ps via the power supply line 24 is formed integral to the common power supply line 24. The second terminal electrode 35b of the second TFT 30B is connected to a pixel electrode 51 via a contact hole 32b formed in the first insulating film 32.

Each subpixel Ps includes at least one of the plurality of capacitors 40. The capacitor 40 is an element for retaining data. The capacitors 40 of the present example are disposed in the first areas A1. The capacitor 40 includes a first capacitor electrode 41, an insulating film including the first insulating film 32, and a second capacitor electrode 43. The capacitor 40 is covered by a second insulating film 42, together with the first TFT 30A and the second TFT 30B.

The capacitor 40 of the present example is formed in the second TFT 30B. More particularly, the capacitor 40 is formed in a portion in which the gate electrode 31b serving as the first capacitor electrode 41 and the second terminal electrode 35b serving as the second capacitor electrode 43 overlap via the semiconductor layer 33b and the first insulating film 32 in the second TFT 30B.

The capacitor 40 of the present example is also formed in a portion in which the second terminal electrode 35a of the first TFT 30A and the gate electrode 31b of the second TFT 30B are located in proximity to the pixel electrode 51. More particularly, the capacitor 40 is formed on the basis of the electric field generated in the horizontal direction of the display screen between the pixel electrode 51 serving as the second capacitor electrode 43 and a combination of the second terminal electrode 35a of the first TFT 30A serving as the first capacitor electrode 41 and the gate electrode 31b of the second TFT 30B via either the base coat film 21 or the first insulating film 32.

The gate lines 22 and the gate electrodes 31a, 31b are all made of the same material and provided in the same layer. The source lines 23, the power supply lines 24, the first terminal electrodes 34a, 34b, the second terminal electrodes 35a, 35b, and the first capacitor electrode 41 are all made of the same material and provided in the same layer. These various wires and electrodes are made of, for example, a metal such as aluminum (Al), tungsten (W), molybdenum (Mo), tantalum (Ta), chromium (Cr), titanium (Ti), or copper (Cu).

The semiconductor layers 33a, 33b are made of a polysilicon. This polysilicon is, for example, an LTPS (low temperature polycrystalline silicon). The semiconductor layers 33a, 33b may be made of an oxide semiconductor. This oxide semiconductor may be, for example, an In—Ga—Zn—O semiconductor. This In—Ga—Zn—O semiconductor may be either amorphous or crystalline.

The base coat film 21, the first insulating film 32, and the second insulating film 42 are made of, for example, an inorganic insulating material such as a silicon oxide, a silicon nitride, or a silicon oxynitride. The base coat film 21, the first insulating film 32, and the second insulating film 42 may be either a monolayer film or a layered film of an inorganic insulating material(s).

Referring to FIG. 4, the plurality of organic EL elements 50 are arranged in the row direction Dx and the column direction Dy, which are orthogonal to each other. The organic EL elements 50 of the present example are provided in the compartmental regions Ap in which the first areas A1 are specified, but not in the compartmental regions Ap in which the second area A2 is specified. The compartmental regions Ap in which the first areas A1 are specified constitute the subpixels Ps. The organic EL element 50 is an example of a light-emitting element.

The plurality of organic EL elements 50 all have a top-emission structure in which the light emitted by an organic EL layer 52 is extracted on the opposite substrate 5 side. Referring to FIG. 8, the organic EL element 50 includes the pixel electrode 51, the organic EL layer 52, and a common electrode 53.

The pixel electrodes 51 are provided in the individual subpixels Ps. The plurality of organic EL elements 50 respectively individually include the pixel electrodes 51. The pixel electrodes 51 are arranged in a manner corresponding to the first areas A1. The pixel electrodes 51 are provided on the base coat film 21. The pixel electrodes 51 are provided in the first areas A1 so as to avoid the gate electrodes 31a, 31b of the first TFTs 30A and the second TFTs 30B. The pixel electrodes 51 are not provided in the second areas A2. The pixel electrodes 51 are reflective to light.

The pixel electrodes 51 are preferably made of a material having a large work function. The pixel electrodes 51 may be made of, for example, a metal such as silver (Ag), aluminum (Al), nickel (Ni), indium (In), or tin (Sn). The pixel electrodes 51 may be made of either a metal compound or a metal alloy. The pixel electrodes 51 may be made of an electrically conductive oxide such as tin oxide (SnO) or zinc oxide (ZnO). The pixel electrodes 51 may be made of a stack of conductive material layers.

Openings 42a are formed in portions of the second insulating film 42 that correspond to the compartmental regions Ap in which each first area A1 is specified. A plurality of openings 32c are formed in the first insulating film 32 so as to expose the pixel electrodes 51 in the openings 42a in the second insulating film 42. The organic EL layer 52 is provided on the pixel electrodes 51 inside the openings 32c formed in the first insulating film 32.

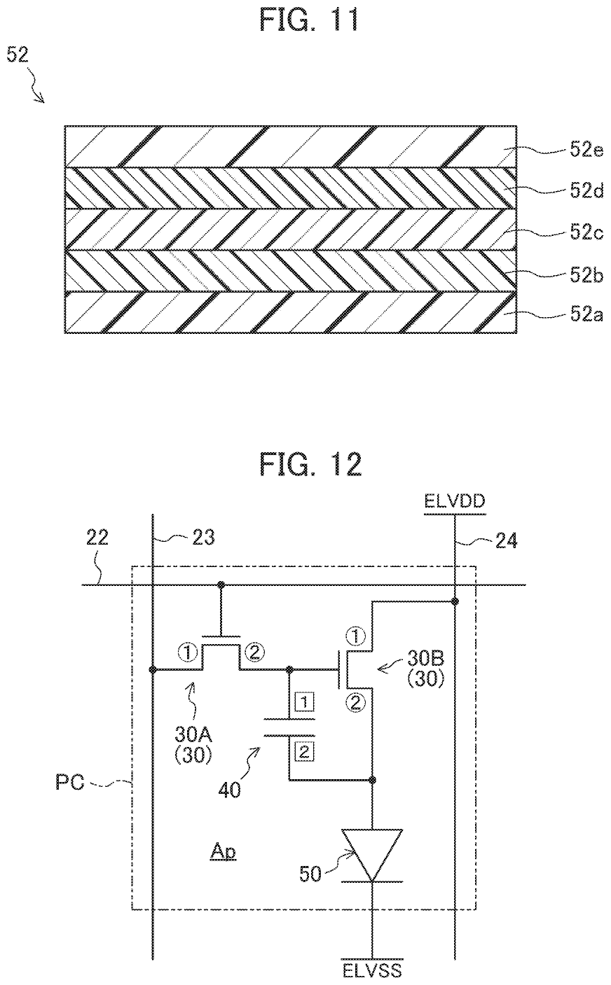

Referring to FIG. 11, the organic EL layer 52 includes a hole injection layer 52a, a hole transport layer 52b, a light-emitting layer 52c, an electron transport layer 52d, and an electron injection layer 52e, all of which are provided sequentially on the pixel electrode 51.

The hole injection layer 52a increases the efficiency of hole injection from the pixel electrodes 51 to the organic EL layer 52. The hole injection layer 52a is made of a well-known compound that matches the work function of the pixel electrode 51 and the molecular orbitals of the hole transport layer 52b. The compound used in the hole injection layer 52a is, for example, an aryl amine, a phthalocyanine, or a Lewis acid-doped organic layer.

The hole transport layer 52b improves the efficiency of hole transport to the light-emitting layer 52c. The hole transport layer 52b is made of a well-known compound that is low in electron affinity and high in hole mobility. The compound used in the hole transport layer 52b is, for example, an aryl amine such as a triphenyl amine derivative.

Upon current application from the pixel electrode 51 and the common electrode 53, the light-emitting layer 52c recombines the holes injected from the pixel electrode 51 and the electrons injected from the common electrode 53 to emit light. The light-emitting layer 52c is made of a well-known compound that is highly fluorescent or phosphorescent and suited to the color of light emitted by the organic EL elements 50 in the individual subpixels Ps (red, green, or blue). The compound used in the light-emitting layer 52c is, for example, an aluminum complex, an anthracene, a rare earth complex, an iridium complex, or one of various fluorescence pigments.

The electron transport layer 52d improves the efficiency of electron transport to the light-emitting layer 52c. The electron transport layer 52d is made of a well-known compound that is high in both electron affinity and electron mobility. The compound used in the electron transport layer 52d is, for example, an aluminum complex such as a quinolinol aluminum complex; an oxadiazole; a triazole; or a phenanthroline.

The electron injection layer 52e improves the efficiency of electron injection from the common electrode 53 to the organic EL layer 52. The electron injection layer 52e is made of a well-known compound that matches the work function of the common electrode 53 and the molecular orbitals of the electron transport layer 52d. The compound used in the electron injection layer 52e is, for example, an alkali metal such as lithium (Li), lithium fluoride, lithium oxide, a lithium complex, or an organic layer doped with an alkali metal.

The common electrode 53 is contiguously provided commonly to the plurality of subpixels Ps. The common electrode 53 extends in the openings 32c in the first areas A1 and provided on the organic EL layer 52. The common electrode 53 runs from inside the openings 42a in the second insulating film 42 onto the second insulating film 42 and spreads so as to cover the first TFTs 30A and the second TFTs 30B via the second insulating film 42. The common electrode 53 is not provided in the second areas A2. The common electrode 53 spreads to the frame area FA and is connected to the second frame line Lb.

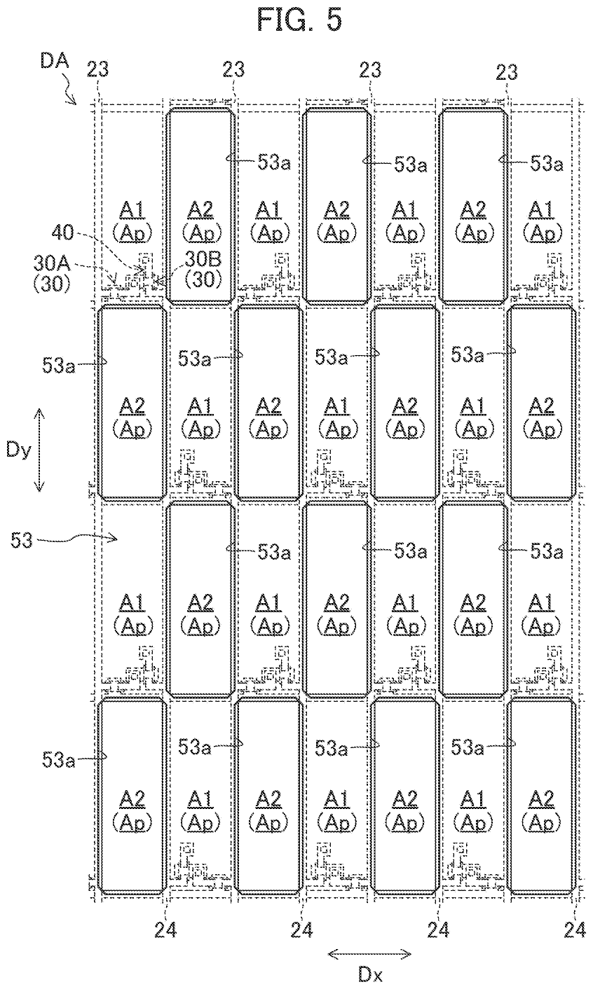

Referring to FIG. 5, the common electrode 53 is further provided in locations that overlap the intersecting portions of the gate lines 22 and the source lines 23 and in locations that overlap the intersecting portions of the gate lines 22 and the power supply lines 24 in a plan view. The portions of the common electrode 53 in obliquely adjacent, first areas A1 are connected together on the four corners. A plurality of openings 53a are formed in the common electrode 53 and arranged in a staggered manner so as to correspond to the second areas A2. The common electrode 53 serves as a cathode for injecting electrons to the organic EL layer 52. The common electrode 53 is transmissive to light.

The common electrode 53 is preferably made of a material having a small work function. The common electrode 53 is made of, for example, an electrically conductive oxide such as indium tin oxide (ITO) or indium zinc oxide (IZO). The common electrode 53 may be made of a metal such as silver (Ag), aluminum (Al), lithium (Li), magnesium (Mg), calcium (Ca), or ytterbium (Yb). The common electrode 53 may be made of either a metal compound or a metal alloy. The common electrode 53 may be made of a stack of conductive material layers.

### Sealing Film

Referring to FIGS. 7 to 10, the sealing film 60 is provided on the element layer 20 so as to cover the plurality of organic EL elements 50. The sealing film 60 protects the organic EL element 50 (especially, the organic EL layer 52) from, for example, moisture. The sealing film 60 has, for example, a TFE (thin film encapsulation) structure. The sealing film 60 is a stack of an inorganic layer, an organic layer, and another inorganic layer. The inorganic layers are made of an inorganic insulating material such as silicon nitride. The organic layer is made of an organic resin material such as an epoxy resin.

The sealing film 60 may have a dam-fill structure. The dam-fill structure includes a dam agent and a fill agent. The dam agent is provided like a frame surrounding the display area DA between the array substrate 3 and the opposite substrate 5. The fill agent fills the internal space of the dam agent. The dam agent and the fill agent serve as adhesives. The dam agent and the fill agent are photocuring adhesives such as an optical transparent resin (OCR).

### Pixel Circuit

The first TFT 30A, the second TFT 30B, the capacitor 40, and the organic EL element 50 in each subpixel Ps constitute the pixel circuit PC shown in FIG. 12. In the equivalent circuit diagram in FIG. 12, the first terminal electrodes 34a, 34b of the first TFT 30A and the second TFT 30B are indicated by a circled numeral 1, and the second terminal electrodes 35a, 35b of the first TFT 30A and the second TFT 30B are indicated by a circled numeral 2. In addition, the first capacitor electrode 41 of the capacitor 40 is indicated by a squared numeral 1, and the second capacitor electrode 43 of the capacitor 40 is indicated by a squared numeral 2.

The pixel circuit PC supplies a drive current to the organic EL element 50 in the corresponding subpixel Ps. The pixel circuit PC operates on the basis of the gate signal supplied to the gate line 22, the source signal supplied to the source line 23, the high-level power supply voltage (ELVDD) supplied to the power supply line 24, and the low-level power supply voltage (ELVSS) supplied to the common electrode 53, to control the emission of light by the organic EL element 50.

In the pixel circuit PC, the gate electrode 31a of the first TFT 30A is connected to an associated one of the gate lines 22. The first terminal electrode 34a of the first TFT 30A is connected to an associated one of the source lines 23. The second terminal electrode 35a of the first TFT 30A is connected to the gate electrode 31b of the second TFT 30B and the first capacitor electrode 41 of the capacitor 40. The first terminal electrode 34b of the second TFT 30B is connected to the power supply line 24. The second capacitor electrode 43 of the capacitor 40 and the second terminal electrode 35b of the second TFT 30B are connected to the pixel electrode 51 of the organic EL element 50.

### First Area

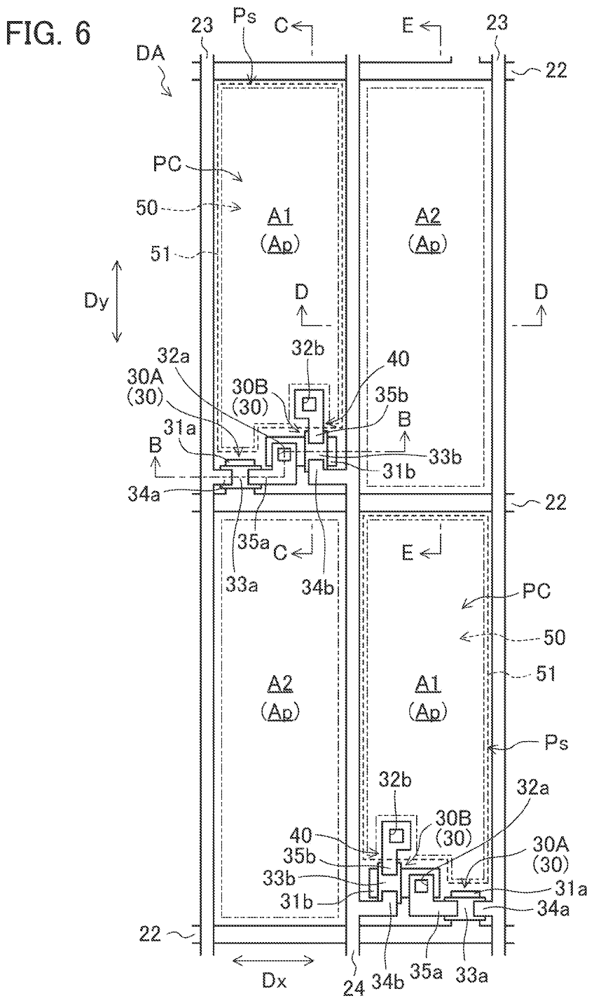

Referring to FIGS. 4 and 6, the pixel circuits PC are provided respectively in the plurality of first areas A1 in the display area DA. Since the pixel circuit PC includes the first TFT 30A, the second TFT 30B, the capacitor 40, and the organic EL element 50, the light coming from behind the organic EL display device 1 is blocked in each first area A1. In each first area A1, the organic EL element 50 is controlled by the pixel circuit PC to emit light. The emission of light in each first area A1 expresses the coloration of the pixel, contributing to image displays.

### Second Area

The pixel circuit PC (the first TFT 30A, the second TFT 30B, the capacitor 40, and the organic EL element 50) is provided in none of the plurality of second areas A2 in the display area DA. Each second area A2 includes the first insulating film 32, the second insulating film 42, the sealing film 60, and the opposite substrate 5. The light coming from behind the organic EL display device 1 is transmitted through each second area A2. The transmission of light through each second area A2 contributes to the visual recognition by the user of the background behind the organic EL display device 1.

### Operation of Organic EL Display Device

In the organic EL display device 1, as the gate line 22 is selected and activated in the subpixel Ps, a gate signal is inputted to the first TFT 30A via the gate line 22, which turns on the first TFT 30A. As the first TFT 30A is turned on, a voltage corresponding to a source signal transferred via the source line 23 is applied to the gate electrode 31b of the second TFT 30B and also written to the capacitor 40. Then, as the second TFT 30B is turned on, a drive current in accordance with the gate voltage of the second TFT 30B is supplied from the power supply line 24 to the organic EL element 50 via the second TFT 30B. Hence, the organic EL layer 52 (light-emitting layer 52c) emits light in the subpixel Ps to display an image.

As described here, the organic EL display device 1 displays an image in accordance with the emission of light by the plurality of subpixels Ps (the first areas A1), by the emission of light by the organic EL elements 50 being controlled through the operations of the first TFT 30A and the second TFT 30B in each of the plurality of organic EL elements 50 arranged in the row direction Dx. Note that the emission of light by the organic EL layer 52 is maintained for each subpixel Ps until a gate signal for a next frame is inputted because the gate voltage of the second TFT 30B is retained by the capacitor 40 even after the first TFT 30A is turned off. Then, in the organic EL display device 1, the background behind the device 1 is visible to the user through the displayed image owing to the light transmitted through the plurality of second areas A2 across the entire display area DA.

### Features of Embodiment 1

In the organic EL display device 1 in accordance with this Embodiment 1, the display area DA includes the plurality of first areas A1 and the plurality of second areas A2 in a mixed manner. The plurality of first areas A1 emit light owing to the organic EL elements 50 to display images in the display area DA. In addition, the plurality of second areas A2 transmit light to cause the display area DA to transmit the background. Hence, the organic EL display device 1 can achieve a high background transmittance as a see-through display device that allows the user to see the background behind the device 1 while displaying images. Then, in the organic EL display device 1, the first areas A1 and the second areas A2 are alternately provided both when viewed in the row direction Dx and when viewed in the column direction Dy. For this reason, the second areas A2 are not arranged straightly both when viewed in the row direction Dx and when viewed in the column direction Dy. This particular structure restrains the background that the user can see through the display area from appearing like stripes on the displayed image in the display area DA.

In the organic EL display device 1 in accordance with this Embodiment 1, the source lines 23 and the power supply lines 24 are alternately provided when viewed in the row direction Dx. Then, the pixel circuits PC are located between the source lines 23 and the power supply lines 24. The source lines 23 and the power supply lines 24 are each used commonly by the plurality of pixel circuits PC included in two columns of subpixels Ps that are adjacent to each other in the row direction Dx. This particular structure eliminates the need to provide the source line 23 and the power supply line 24 for each column of subpixels Ps, which can reduce the number of wires. Therefore, the second areas A2 can have an increased aperture ratio by reducing or eliminating the wires disposed in the second areas A2.

In the organic EL display device 1 in accordance with this Embodiment 1, the source lines 23 and the power supply lines 24 are made of the same material and provided in the same layer. For this reason, the display area DA can have a simple layer structure in comparison with when the source lines 23 and the power supply lines 24 are made in separate layers. That the source lines 23 and the power supply lines 24 are each used commonly by the plurality of pixel circuits PC included in two columns of subpixels Ps that are adjacent to each other in the row direction Dx when the source lines 23 and the power supply lines 24 are made in the same layer as described here is especially advantageous in reducing or eliminating the wires disposed in the second areas A2.

In the organic EL display device 1 in accordance with this Embodiment 1, the first areas A1 and the second areas A2 are specified in the compartmental regions Ap compartmentalized by the gate lines 22, the source lines 23, and the power supply lines 24. The first areas A1 and the second areas A2 specified in the compartmental regions Ap are so small that the user can hardly visually recognize the first areas A1 and the second areas A2 individually. Therefore, natural transparency can be imparted to the background that is visible through the displayed image as the see-through display device.

### First Variation Example

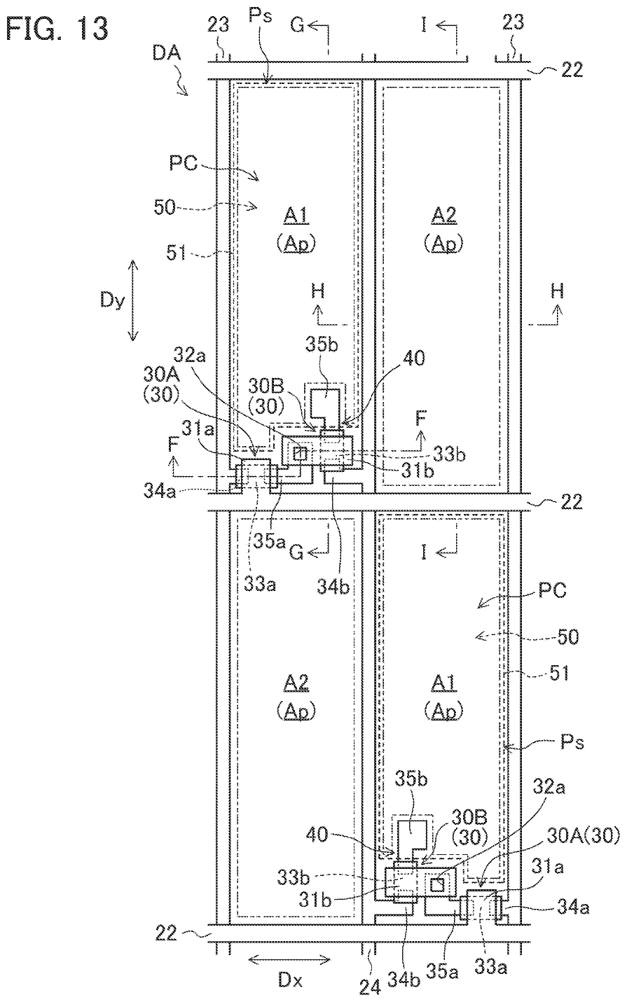

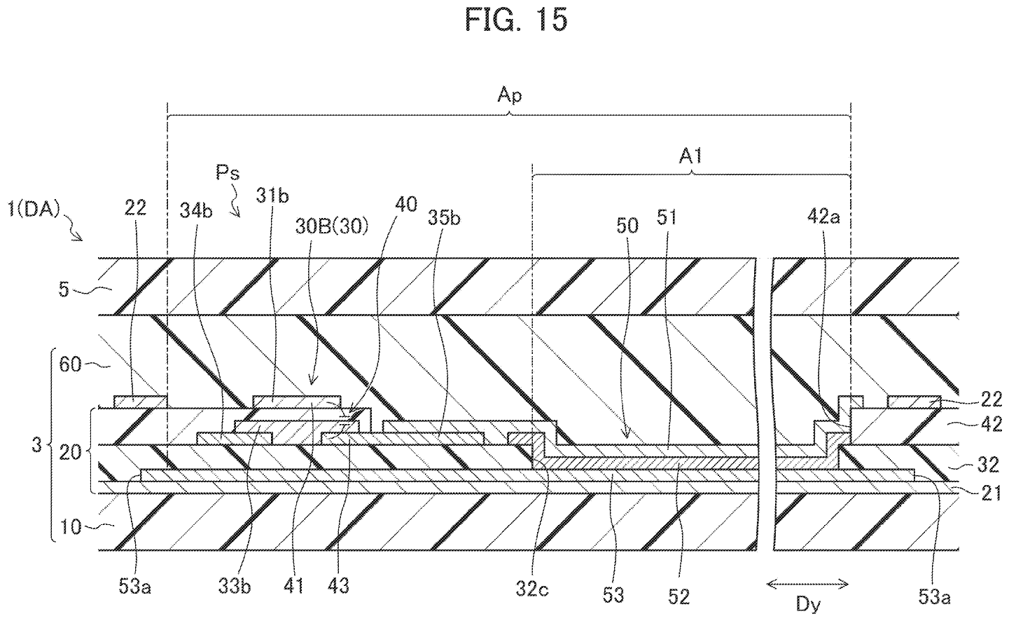

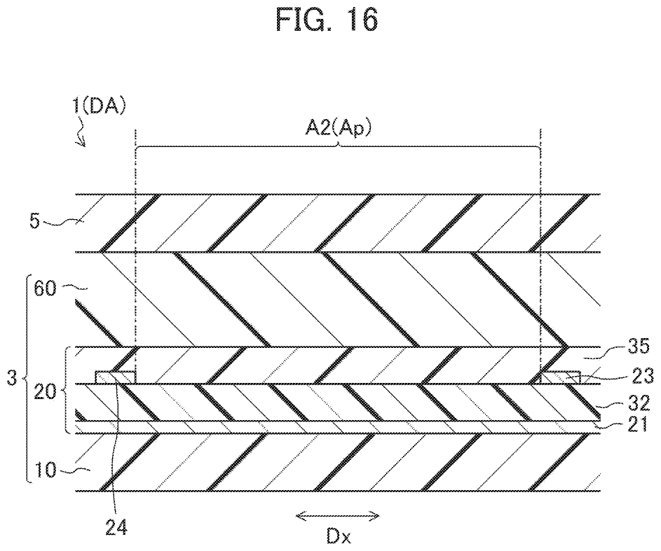

Referring to FIGS. 13 to 15, in the organic EL display device 1 of this first variation example, the first TFT 30A and the second TFT 30B in each subpixel Ps have a top-gate structure. The plurality of gate lines 22 are provided on the second insulating film 42. The plurality of source lines 23 and the plurality of power supply lines 24 are provided on the first insulating film 32 and covered by the second insulating film 42.

The first terminal electrodes 34a, 34b and the second terminal electrodes 35a, 35b are provided on the first insulating film 32 and covered by the second insulating film 42. The semiconductor layers 33a, 33b are provided as a layer overlying the first terminal electrodes 34a, 34b and the second terminal electrodes 35a, 35b. The semiconductor layers 33a, 33b extend between the first terminal electrodes 34a, 34b and the second terminal electrodes 35a, 35b and are connected partially overlapping the first terminal electrodes 34a, 34b and the second terminal electrodes 35a, 35b. The gate electrodes 31a, 31b are provided on the second insulating film 42.

The gate electrode 31b of the second TFT 30B is connected to the second terminal electrode 35a of the first TFT 30A via a contact hole 42b in the second insulating film 42. The second terminal electrode 35b of the second TFT 30B is exposed inside the opening 42a in the second insulating film 42. The pixel electrode 51 of the present example is provided inside the opening 42a in the second insulating film 42 and connected partially overlapping the second terminal electrode 35b of the second TFT 30B.

The capacitor 40 of the present example is also provided in the second TFT 30B. More particularly, the capacitor 40 is formed in a portion in which the gate electrode 31b serving as the first capacitor electrode 41 and the second terminal electrode 35b serving as the second capacitor electrode 43 overlap via the semiconductor layer 33b and the second insulating film 42 in the second TFT 30B.

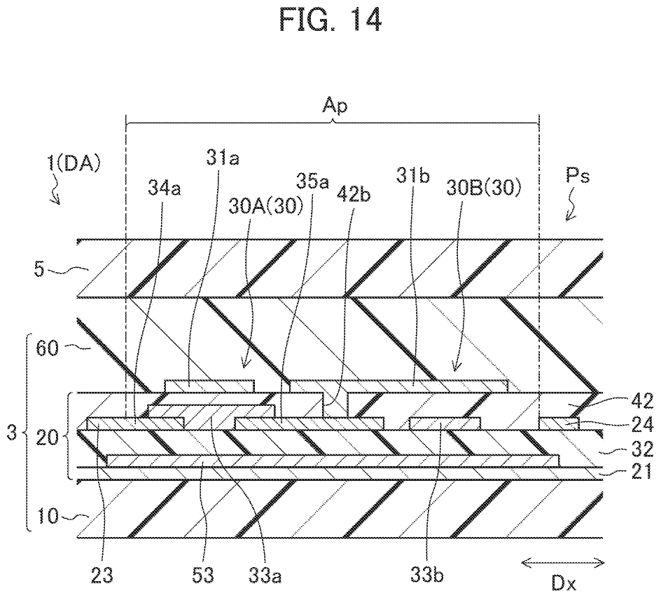

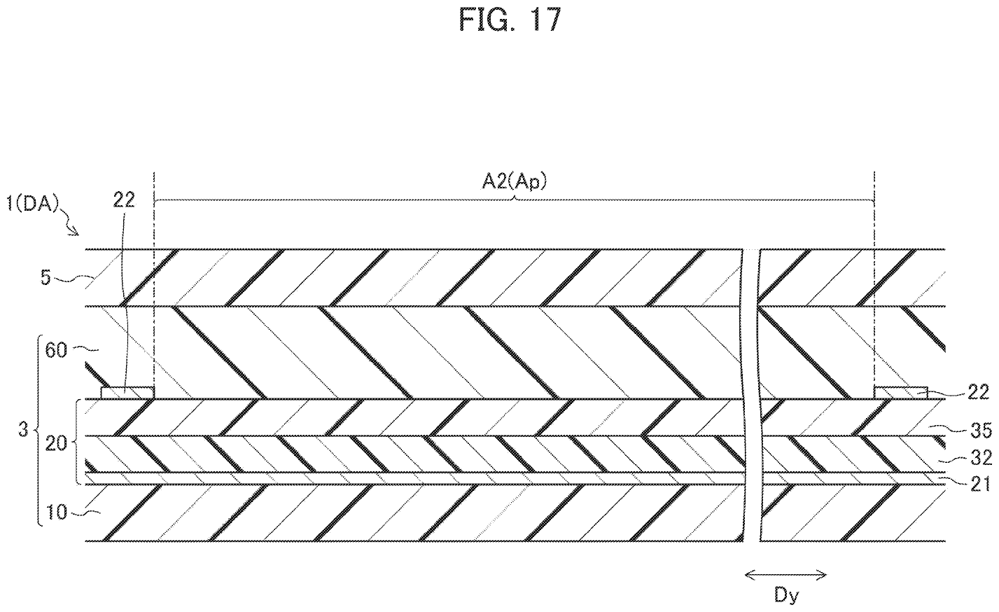

Referring to FIGS. 14 to 17, the common electrode 53 of the present example is again provided in the first areas A1, but not in the second areas A2. The common electrode 53 is located as a layer underlying the first insulating film 32. Similarly to Embodiment 1 above, a plurality of openings 53a are formed in the common electrode 53 and arranged in a staggered manner so as to correspond to the second areas A2. The common electrode 53 is provided on the base coat film 21 and covered by the first insulating film 32.

Each second area A2 of the present example again includes the first insulating film 32, the second insulating film 42, the sealing film 60, and the opposite substrate 5. Openings 32d for exposing the common electrode 53 are formed in portions of the first insulating film 32 that correspond to the first areas A1. The organic EL layer 52 is provided inside the openings 32d in the first insulating film 32 and disposed between the common electrode 53 and the pixel electrodes 51. The common electrode 53 and the pixel electrodes 51 face each other via the organic EL layer 52 to form the organic EL elements 50.

### Second Variation Example

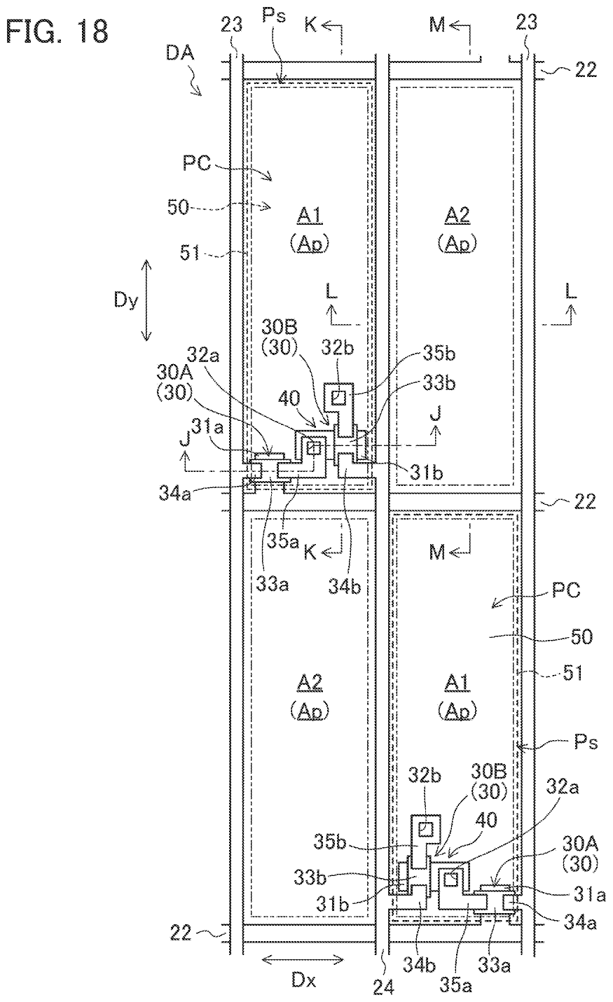

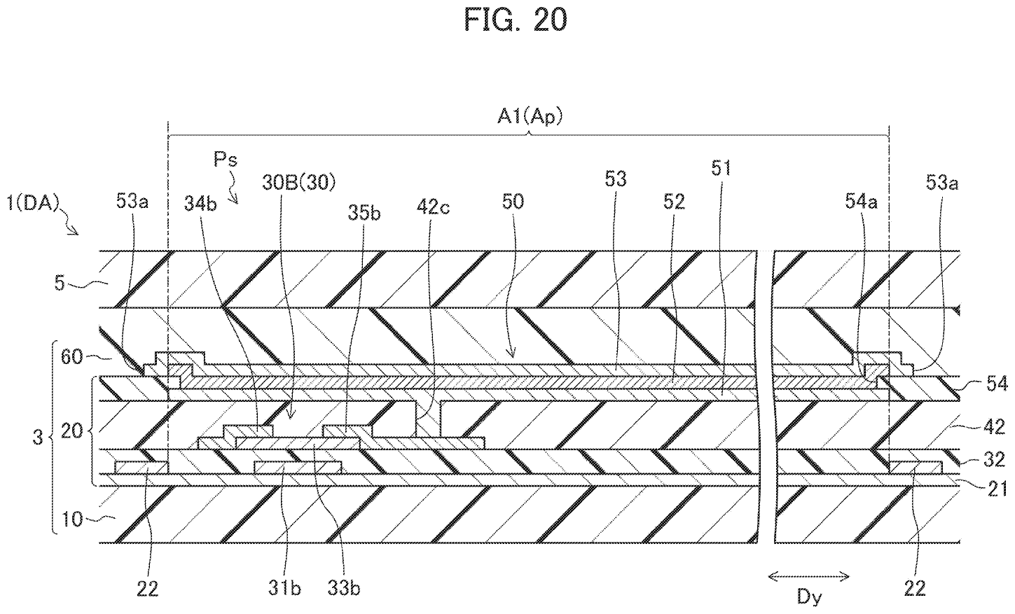

Referring to FIGS. 18 to 20, in the organic EL display device 1 of this second variation example, the organic EL element 50 is provided on the second insulating film 42 and covered by the sealing film 60. The organic EL element 50 of the present example is further provided in portions corresponding to the first TFT 30A, the second TFT 30B, and the capacitor 40 in each subpixel Ps. The first area A1 includes those portions of the compartmental region Ap in which the first TFT 30A, the second TFT 30B, and the capacitor 40 are provided.

The plurality of pixel electrodes 51 are provided on the surface of the second insulating film 42. Each pixel electrode 51 is connected to the second terminal electrode 35b of an associated one of the second TFTs 30B via a contact hole 42c formed in the second insulating film 42. Adjacent pixel electrodes 51 are compartmentalized by an edge cover 54. The edge cover 54 is provided so as to cover a peripheral portion of each pixel electrode 51. The organic EL layer 52 is provided on the individual pixel electrodes 51 inside openings 54a in the edge cover 54.

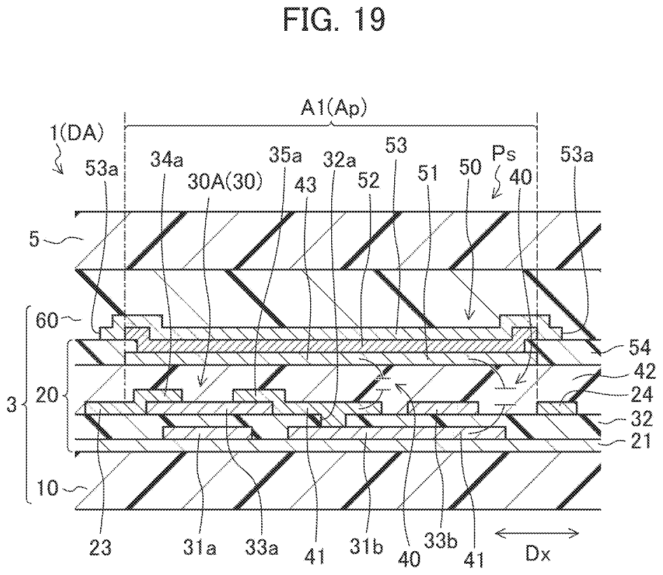

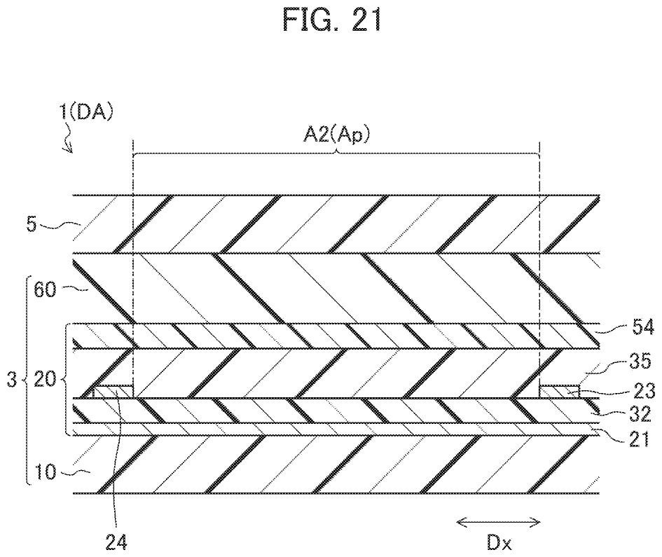

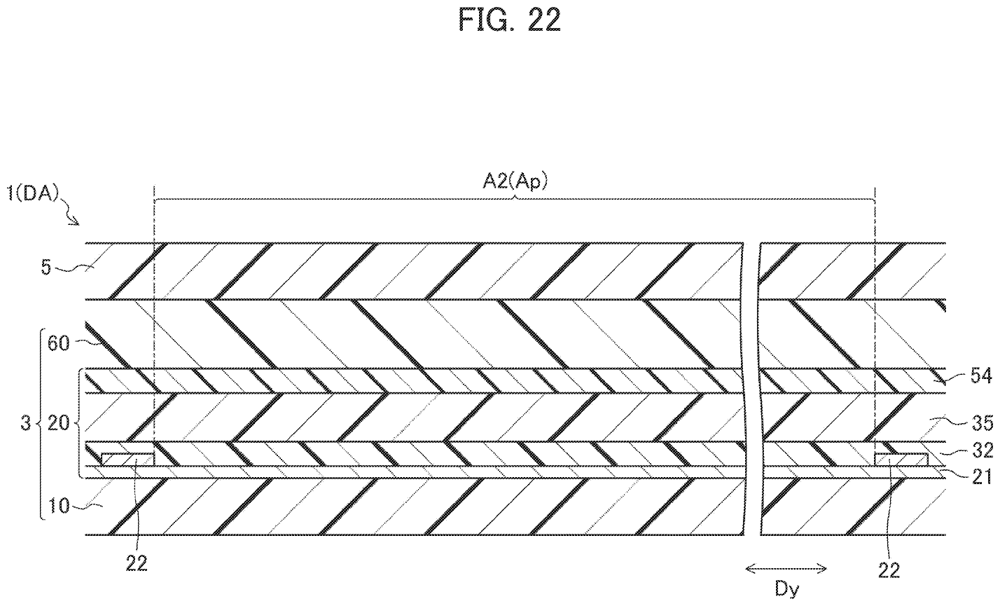

Referring to FIGS. 19 to 22, the common electrode 53 of the present example is again provided in the first areas A1, but not in the second areas A2. Similarly to Embodiment 1 above, a plurality of openings 53a are formed in the common electrode 53 and arranged in a staggered manner so as to correspond to the second areas A2. The common electrode 53 is provided so as to cover the organic EL layers 52. The common electrode 53 is located facing the plurality of pixel electrodes 51 via the organic EL layer 52.

The capacitor 40 of the present example is again provided in the second TFT 30B and also in a portion in which the second terminal electrode 35b of the first TFT 30A and the gate electrode 31b of the second TFT 30B overlap the pixel electrode 51. More particularly, the capacitor 40 includes a portion in which the second terminal electrode 35a of the first TFT 30A serving as the first capacitor electrode 41 and the pixel electrode 51 serving as the second capacitor electrode 43 overlap each other via the second insulating film 42. The capacitor 40 further includes a portion in which the gate electrode 31b of the second TFT 30B serving as the first capacitor electrode 41 and the pixel electrode 51 serving as the second capacitor electrode 43 overlap each other via the first insulating film 32 and the second insulating film 42.

### Third Variation Example

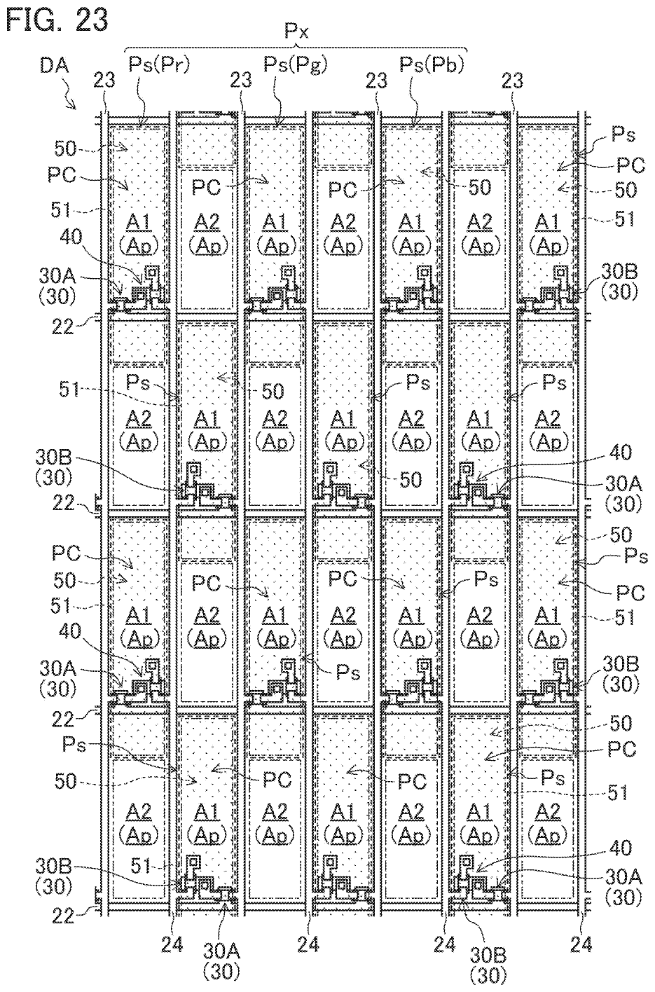

Referring to FIG. 23, in the organic EL display device 1 of this third variation example, each first area A1 is specified across two compartmental regions Ap that are adjacent to each other in the column direction. The first area A1 of the present example is specified substantially across the entire compartmental region Ap in which the first TFT 30A, the second TFT 30B, and the capacitor 40 are provided and in a portion of the compartmental region Ap adjacent to a side (the bottom side in the example shown in FIG. 23) of that compartmental region Ap in the column direction Dy in the second area A2.

In the present example, the organic EL element 50 is again provided on the second insulating film 42 and covered by the sealing film 60, similarly to the second variation example. The organic EL element 50 spreads so as to cover the first TFT 30A, the second TFT 30B, and the capacitor 40 in a plan view. The organic EL element 50 overlaps the gate line 22 via the first insulating film 32 and the second insulating film 42 and is provided across the two compartmental regions Ap in which the first area A1 and the second area A2 are specified and that are adjacent in the column direction Dy.

The organic EL element 50 extends from the compartmental region Ap in which the first area A1 is specified, intersects with an associated one of the gate lines 22 via the first insulating film 32 and the second insulating film 42, and extends further to the compartmental region Ap in which the second area A2 is specified. That portion of the organic EL element 50 that extends to the compartmental region Ap in which the second area A2 is specified is provided on a side (the top side in in FIG. 23) of the compartmental region Ap in the column direction Dy. For this reason, the first area A1 is expanded beyond the single compartmental regions Ap, whereas the second area A2 is reduced relatively in area.

The first area A1 is larger in area than the second area A2 in the present example. The first area A1, when larger in area than the second area A2, adds to the light-emission area that contributes to the image display in the display area DA. Hence, the organic EL display device 1 can both serve as a see-through display device and produce high quality image displays with emphasis on image displays in the display area DA.

### Fourth Variation Example

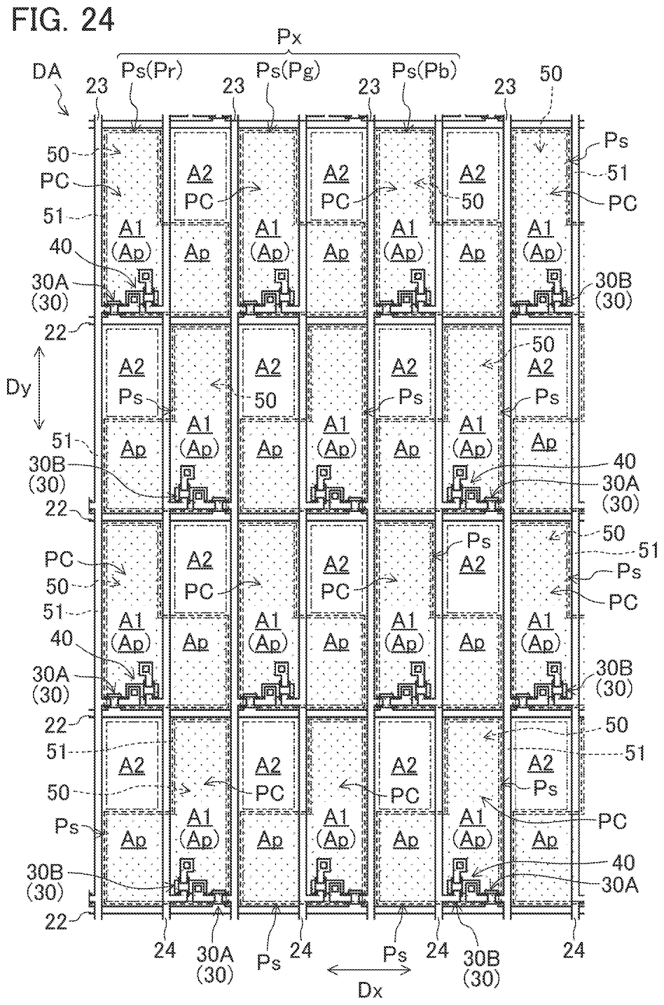

Referring to FIG. 24, in the organic EL display device 1 of this fourth variation example, the first area A1 is specified across two compartmental regions Ap that are adjacent in the row direction Dx. The first area A1 of the present example is specified substantially across the entire compartmental region Ap in which the first TFT 30A, the second TFT 30B, and the capacitor 40 are provided and in a portion of the compartmental region Ap adjacent to a side (the power supply line 24 side in the example shown in FIG. 24) of that compartmental region Ap in the row direction Dx in the second area A2.

In the present example, the organic EL element 50 is again provided on the second insulating film 42 and covered by the sealing film 60, similarly to the second variation example. The organic EL element 50 spreads so as to cover the first TFT 30A, the second TFT 30B, and the capacitor 40 in a plan view. The organic EL element 50 overlaps the power supply line 24 via the second insulating film 42 and is provided across the two compartmental regions Ap in which the first area A1 and the second area A2 are specified and that are adjacent in the row direction Dx.

The organic EL element 50 extends from the compartmental region Ap in which the first area A1 is specified, intersects with an associated one of the power supply lines 24 via the second insulating film 42, and extends further to the compartmental region Ap in which the second area A2 is specified. That portion of the organic EL element 50 that extends to the compartmental region Ap in which the second area A2 is specified is provided on a side (the bottom side in FIG. 24) of the compartmental region Ap in the column direction Dy. For this reason, the first area A1 is expanded beyond the single compartmental region Ap, whereas the second area A2 is reduced relatively in area.

The first area A1 is larger in area than the second area A2 again in the present example. Therefore, similarly to the third variation example above, the organic EL display device 1 can both serve as a see-through display device and produce high quality image displays with emphasis on image displays in the display area DA.

### Fifth Variation Example

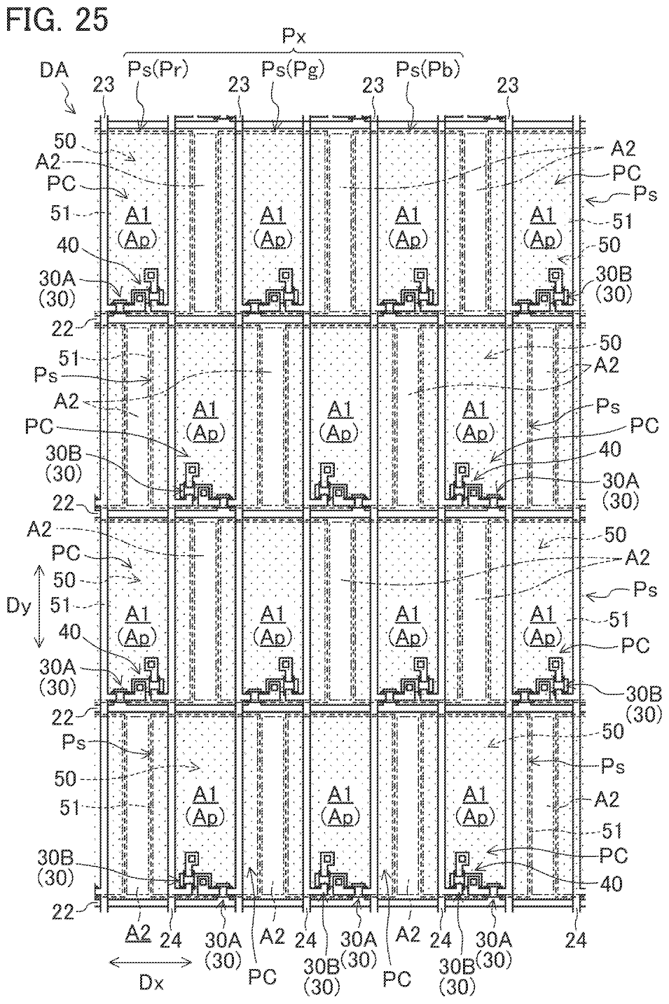

Referring to FIG. 25, in the organic EL display device 1 of this fifth variation example, the first area A1 is specified across three compartmental regions Ap that are adjacent in the row direction Dx. The first area A1 of the present example is specified substantially across the entire compartmental region Ap in which the first TFT 30A, the second TFT 30B, and the capacitor 40 are provided and in portions of the compartmental regions Ap adjacent to either side of that compartmental region Ap in the row direction Dx in the second area A2.

In the present example, the organic EL element 50 is again provided on the second insulating film 42 and covered by the sealing film 60, similarly to the second variation example. The organic EL element 50 spreads so as to cover the first TFT 30A, the second TFT 30B, and the capacitor 40 in a plan view. The organic EL element 50 overlaps the source line 23 and the power supply line 24 via the second insulating film 42 and is provided across the three compartmental regions Ap in which the first area A1 and the second area A2 are specified and that are adjacent in the row direction Dx.

The organic EL element 50 extends from the compartmental region Ap in which the first area A1 is specified, intersects with an associated one of the source lines 23 and an associated one of the power supply lines 24 via the second insulating film 42, and extends further to the two compartmental regions Ap in which the second area A2 is specified. That portion of the organic EL element 50 that extends to each compartmental region Ap in which the second area A2 is specified is provided on a side of the compartmental region Ap in the row direction Dx. For this reason, the first area A1 is expanded beyond the single compartmental region Ap, whereas the second area A2 is reduced relatively in area.

The first area A1 is larger in area than the second area A2 again in the present example. Therefore, similarly to the third variation example above, the organic EL display device 1 can both serve as a see-through display device and produce high quality image displays with emphasis on image displays in the display area DA.

### Sixth Variation Example

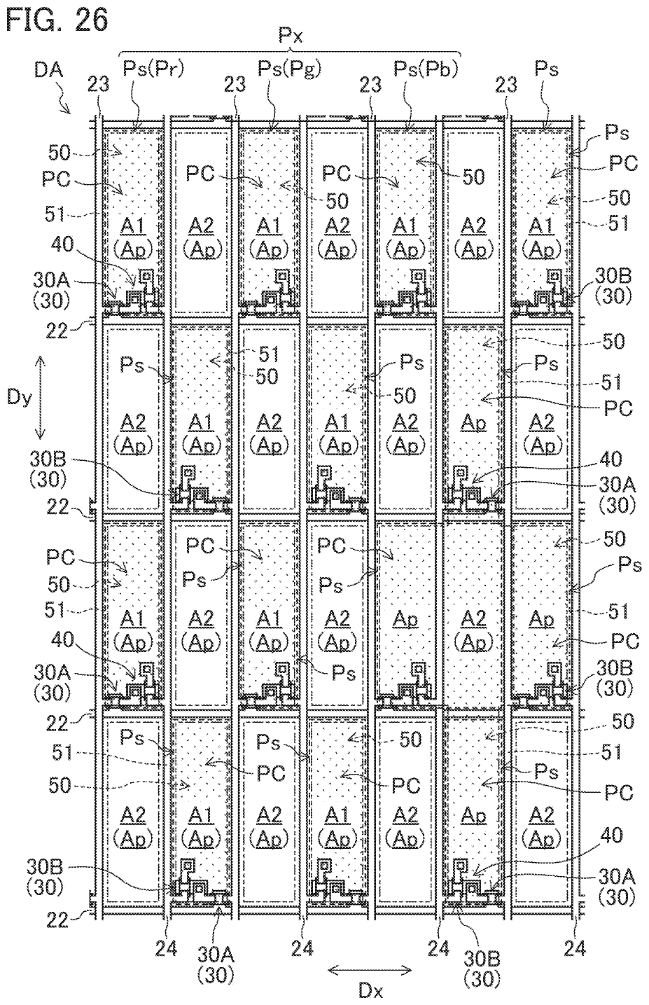

Referring to FIG. 26, in the organic EL display device 1 of this sixth variation example, some of the first areas A1 are specified across five compartmental regions Ap that are arranged like a cross. These first areas A1 of the present example are specified substantially across the two entire compartmental regions Ap in each of which the first TFT 30A, the second TFT 30B, and the capacitor 40 are provided and that are adjacent to each other in the row direction Dx, substantially across the entire compartmental region Ap located between these two compartmental regions Ap, and substantially across the two compartmental regions Ap that are adjacent to either side of that compartmental region Ap in the column direction Dy.

In the present example, the organic EL element 50 is again provided on the second insulating film 42 and covered by the sealing film 60, similarly to the second variation example. Each first area A1 that is provided across the five compartmental regions Ap is formed by four organic EL elements 50. One of the organic EL elements 50 covers the first TFT 30A, the second TFT 30B, and the capacitor 40 in a plan view, intersects with an associated one of the power supply lines 24 via the second insulating film 42, and extends to the compartmental region Ap in which the first TFT 30A, the second TFT 30B, and the capacitor 40 are not provided.

Another one of the organic EL elements 50 is provided in the compartmental region Ap that is adjacent in the row direction Dx to a side of the compartmental region Ap in which the foregoing organic EL element 50 is provided, but in which the first TFT 30A, the second TFT 30B, and the capacitor 40 are not provided. The remaining two organic EL elements 50 are provided in the respective compartmental regions Ap that are adjacent in the column direction Dy to either side of the compartmental region Ap in which the foregoing organic EL element 50 is provided, but in which the first TFT 30A, the second TFT 30B, and the capacitor 40 are not provided.

The five adjacent compartmental regions Ap in which the organic EL elements 50 are provided may be regarded as a single first area A1. This technique of expanding the first area A1 is advantageous in enabling the organic EL display device 1 to both serve as a see-through display device and clearly display information such as prescribed text and graphics in the display area DA.

### Seventh Variation Example

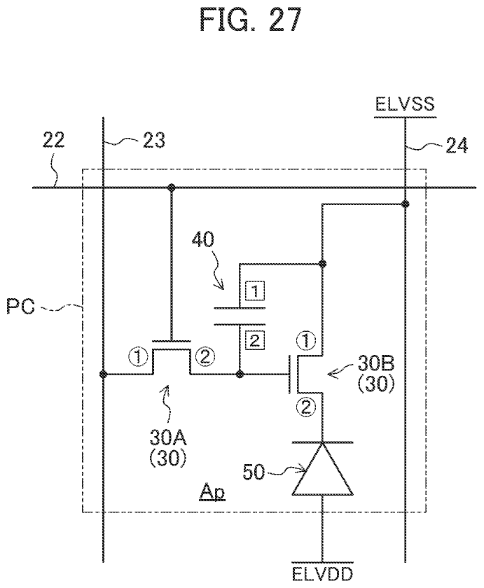

In the organic EL display device 1 of this seventh variation example, the pixel electrode 51 serves as a cathode, and the common electrode 53 serves as an anode. Referring to FIG. 27, the power supply line 24 is fed with a low-level power supply voltage (ELVSS) via the first frame line La. The common electrode 53 of the organic EL element 50 is fed with a high-level power supply voltage (ELVDD) via the second frame line Lb.

In the pixel circuit PC of the present example, the second capacitor electrode 43 of the capacitor 40 is connected to the power supply line 24, together with the first terminal electrode 34b of the second TFT 30B. The organic EL layer 52 of the present example has a layered structure in which the organic EL layer 52 in accordance with foregoing Embodiment 1 is reversed. The organic EL layer 52 includes an electron injection layer 52e, an electron transport layer 52d, a light-emitting layer 52c, a hole transport layer 52b, and a hole injection layer 52a, all of which are provided sequentially on the pixel electrode 51.

### Embodiment 2

An organic EL display device 1 in accordance with this Embodiment 2 differs from foregoing Embodiment 1 in the structure of the first area A1 and the second area A2. Note that in this and subsequent embodiments, the organic EL display device 1 is structured in the same manner as in foregoing Embodiment 1, except that the first areas A1 and the second areas A2 have a different configuration than in foregoing Embodiment 1. Thus, the description will focus on the first areas A1 and the second areas A2 that have a different configuration.

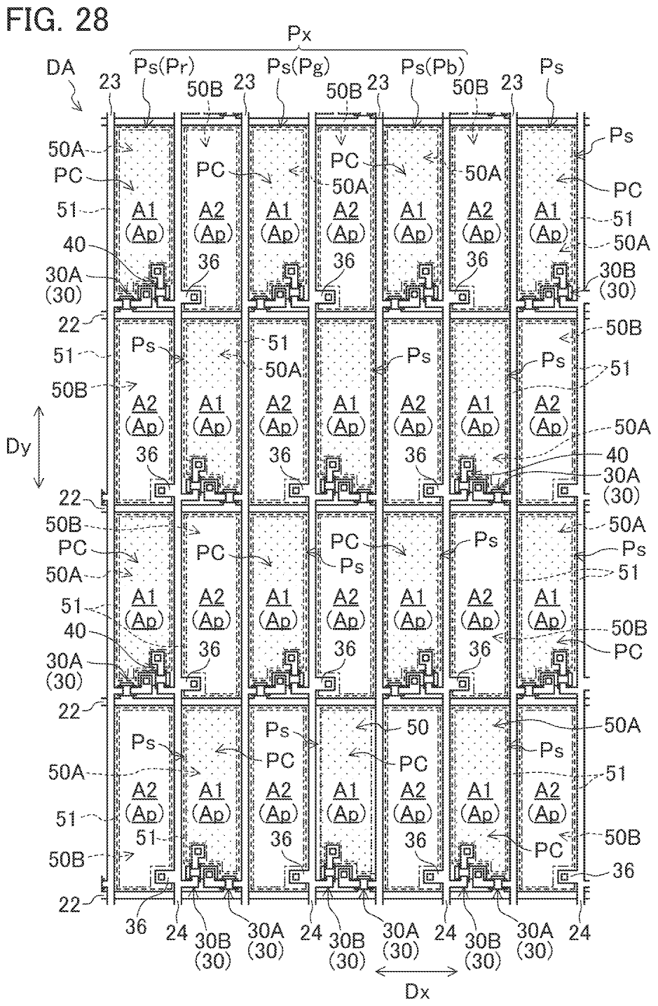

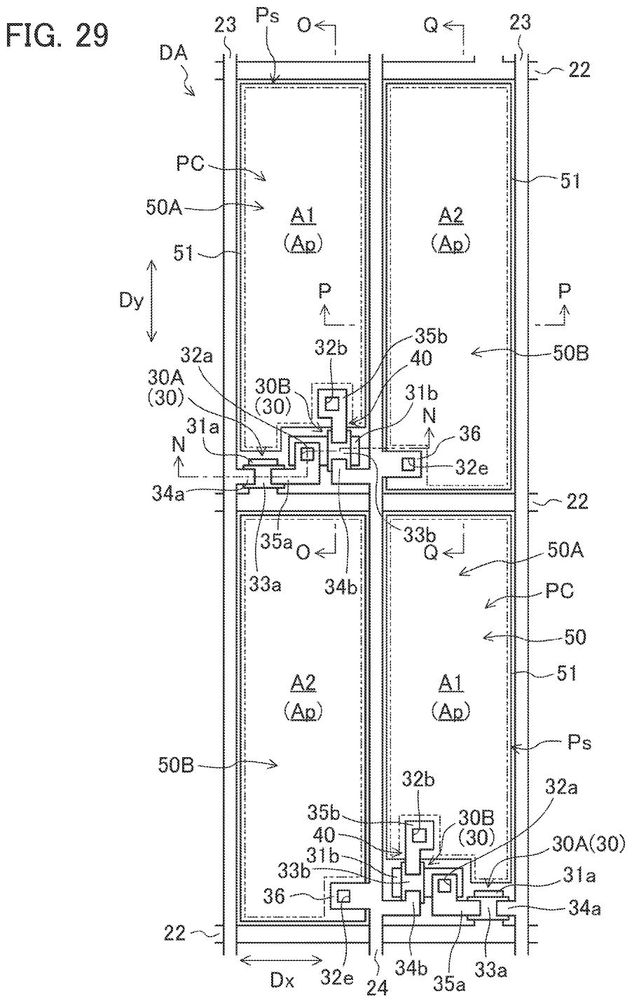

Referring to FIGS. 28 and 29, in the organic EL display device 1 in accordance with this Embodiment 2, first organic EL elements 50A as light-emitting elements are provided in the first areas A1, and second organic EL elements 50B as light-emitting elements are provided in the second areas A2. The first organic EL elements 50A have a top-emission structure. The second organic EL elements 50B have a top- and bottom-emission structure in which the light emitted by the organic EL layer 52 is extracted both through the base substrate 10 side and through the opposite substrate 5 side.

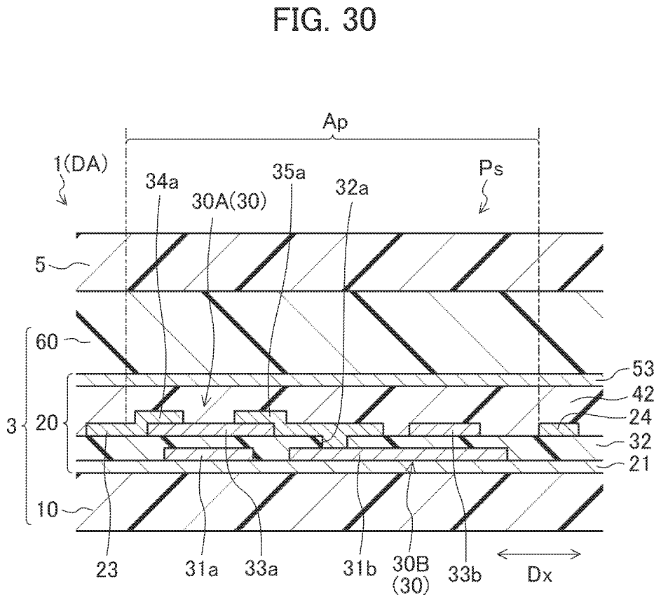

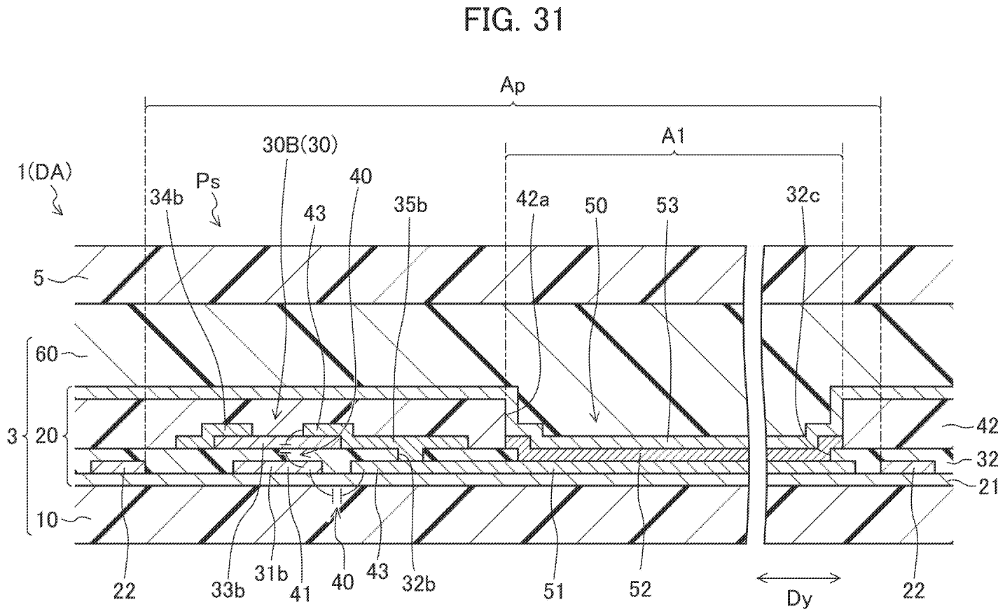

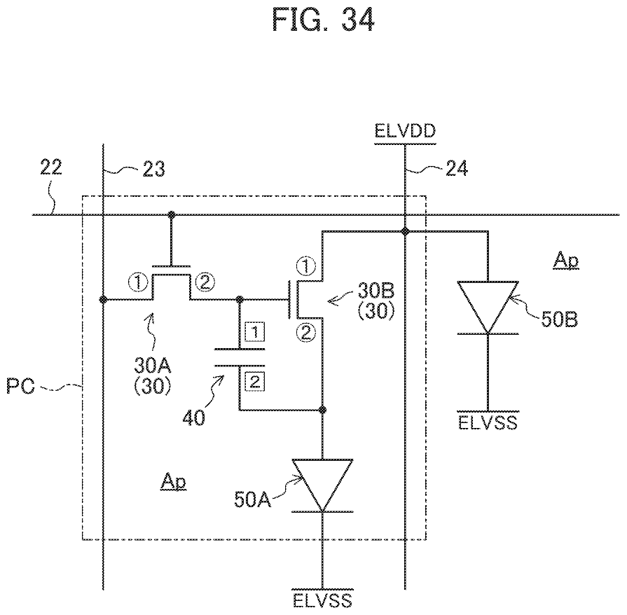

The plurality of first areas A1 are structured in the same manner as in foregoing Embodiment 1. Each first area A1 includes a pixel circuit PC. Referring to FIG. 34, the pixel circuit PC includes a first TFT 30A, a second TFT 30B, a capacitor 40, and one of the first organic EL elements 50A. Referring to FIGS. 30 and 31, the first TFT 30A, the second TFT 30B, and the capacitor 40 are structured in the same manner as in foregoing Embodiment 1. The first organic EL element 50A is structured in the same manner as the foregoing organic EL element 50 in accordance with Embodiment 1.

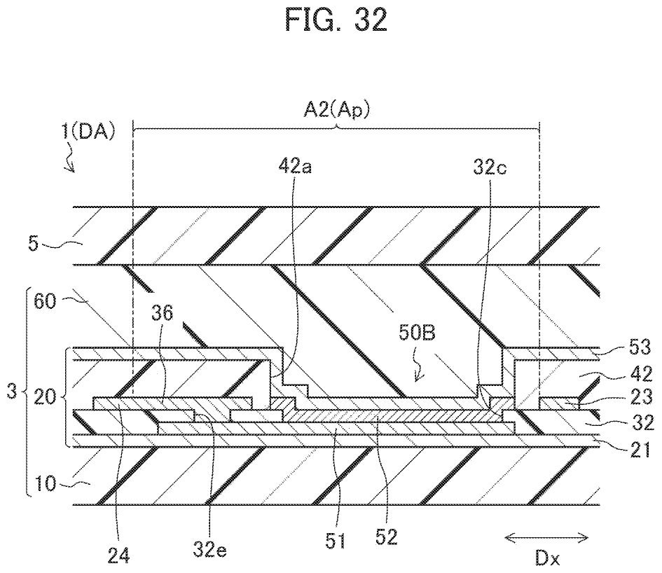

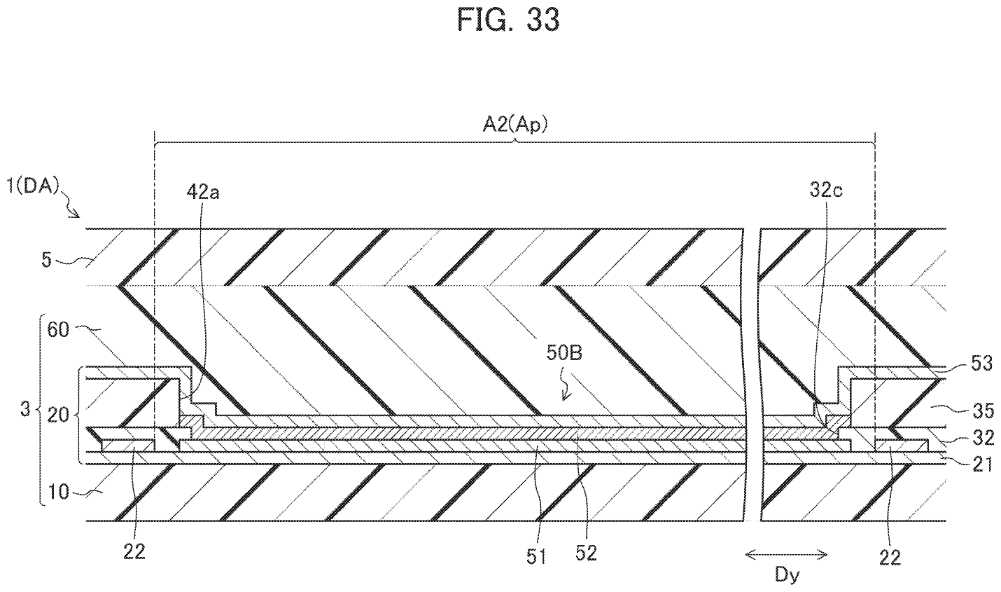

As further shown in FIGS. 32 and 33, in the present example, each second area A2 includes one of the second organic EL elements 50B and a drive electrode 36. The second organic EL element 50B includes a pixel electrode 51, an organic EL layer 52, and a common electrode 53. The plurality of second organic EL elements 50B individually include the pixel electrodes 51. The pixel electrodes 51 are arranged corresponding to the second areas A2. The pixel electrodes 51 are provided on the base coat film 21.

The pixel electrode 51 of the second organic EL element 50B is transmissive to light. For this reason, the second organic EL element 50B is itself transmissive to light. The pixel electrode 51 of the second organic EL element 50B is made of a different material than the pixel electrode 51 of the first organic EL element 50A. The pixel electrode 51 of the present example is specified in a suitable manner appropriately for the intended use of the organic EL display device 1 because the pixel electrode 51 can affect, for example, the display quality of images displayed in the display area DA and how the background that is visible through these displayed images appears.

The organic EL layer 52 of the second organic EL element 50B is structured in the same manner as the organic EL layer 52 of the first organic EL element 50A. The light-emitting layer 52c of the second organic EL element 50B is made of the same material to match the color of emitted light with the light-emitting layers 52c of the first organic EL elements 50A provided in the surrounding subpixels Ps. The common electrode 53 of the first organic EL element 50A and the common electrode 53 of the second organic EL element 50B are formed integrally. The common electrode 53 is provided across the entire display area DA so as to be used commonly by the plurality of first areas A1 and the plurality of second areas A2.

The drive electrode 36 is provided on the first insulating film 32. The drive electrode 36 is disposed close to a corner of the compartmental region Ap in which the second area A2 is specified, the corner being on the power supply line 24 side. The drive electrode 36 is formed integrally to an associated one of the power supply lines 24. The drive electrode 36 is connected to the pixel electrode 51 of the second organic EL element 50B via a contact hole 32e formed in the first insulating film 32. As further shown in FIG. 34, the pixel electrode 51 of the second organic EL element 50B is connected to the power supply line 24 via the drive electrode 36.

### Features of Embodiment 2

In the organic EL display device 1 in accordance with this Embodiment 2, each compartmental region Ap, which is a part of the second area A2, includes one second organic EL element 50B. The pixel electrode 51 of the second organic EL element 50B is fed with a high-level power supply voltage (ELVDD) from the power supply line 24 via the drive electrode 36. When an image is to be displayed by controlling the emission of light in the first area A1 by each first organic EL element 50A, the second organic EL element 50B is also fed with a drive current from the power supply line 24. For this reason, the organic EL layer 52 (light-emitting layer 52c) in each second organic EL element 50B emits light, turning on each second area A2. As described here, the display area DA of the organic EL display device 1 displays an image in a blind state in which the background behind the device 1 is not visible.

In addition, in the organic EL display device 1 in accordance with this Embodiment 2, by rendering the signal transferred by either the gate line 22 or the source line 23 such a signal that the organic EL layer 52 in the first organic EL element 50A does not emit light under the control of the pixel circuit PC, only the organic EL layer 52 (light-emitting layer 52c) in each second organic EL element 50B emits light, which turns on the display area DA as a whole. By doing so, the display area DA of the organic EL display device 1 is capable of being turned on in a blind state in which the background behind the device 1 is not visible.

Then, in the organic EL display device 1 in accordance with this Embodiment 2, when each first organic EL element 50A is not activated, and no images are displayed, the first frame line La and the second frame line Lb are not fed with a power supply voltage, therefore, the organic EL layer 52 of each second organic EL element 50B does not emit light, and each second area A2 is not turned on. For this reason, the background behind the organic EL display device 1 is visible to the user across the entire display area DA. As described here, the display area DA of the organic EL display device 1 is in a see-through state in which the background behind the device 1 is visible through the display area DA.

### First Variation Example

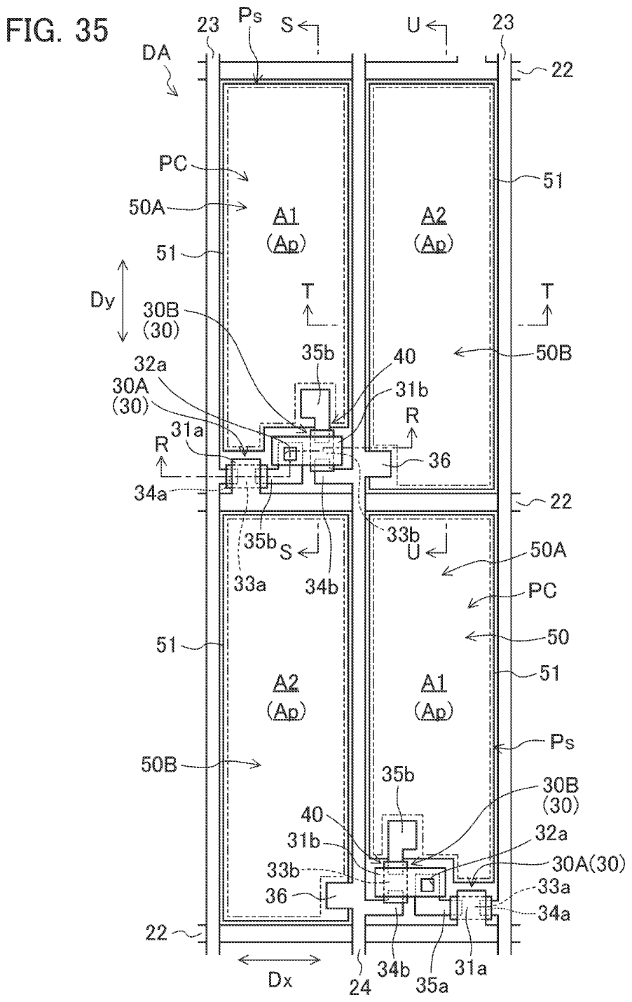

Referring to FIG. 35, in the organic EL display device 1 of this first variation example, the first TFTs 30A and the second TFTs 30B in the subpixels Ps have a top-gate structure. The plurality of gate lines 22 are provided on the second insulating film 42. The plurality of source lines 23 and the plurality of power supply lines 24 are provided on the first insulating film 32 and covered by the second insulating film 42.

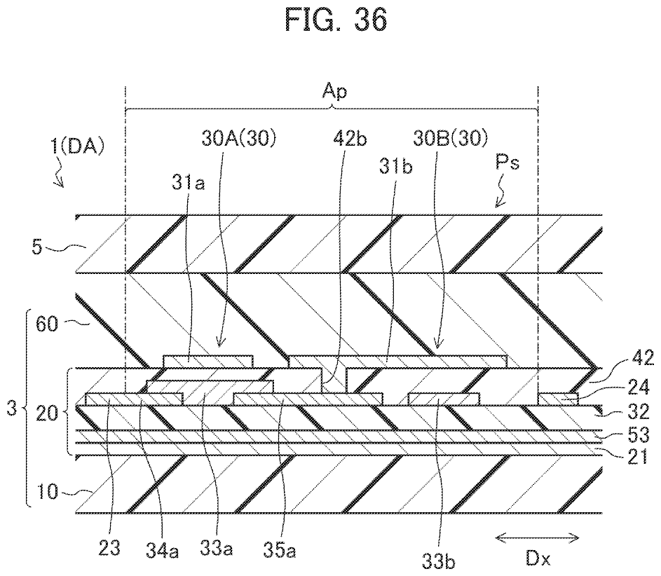

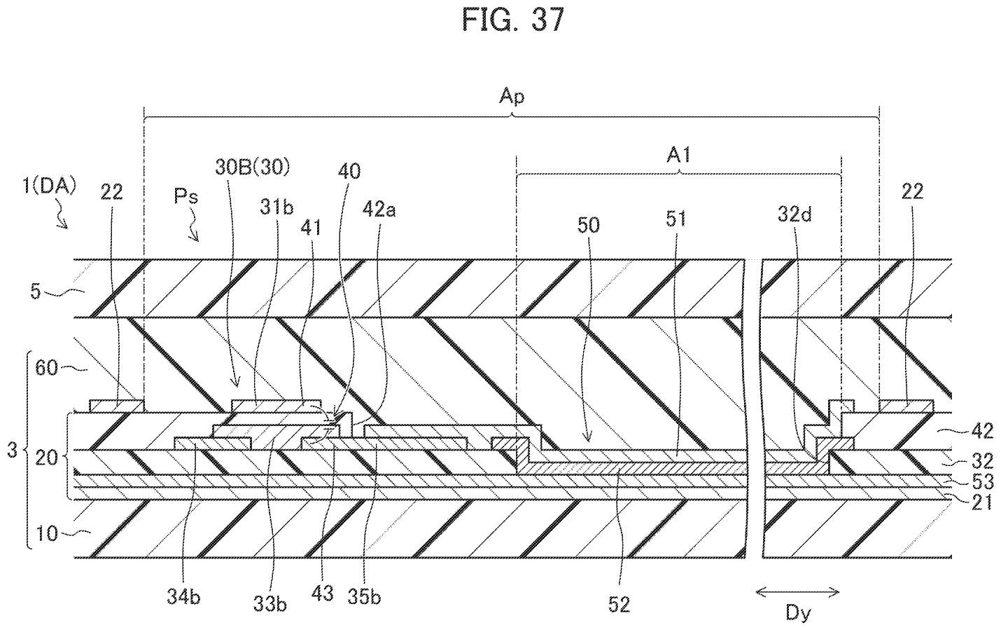

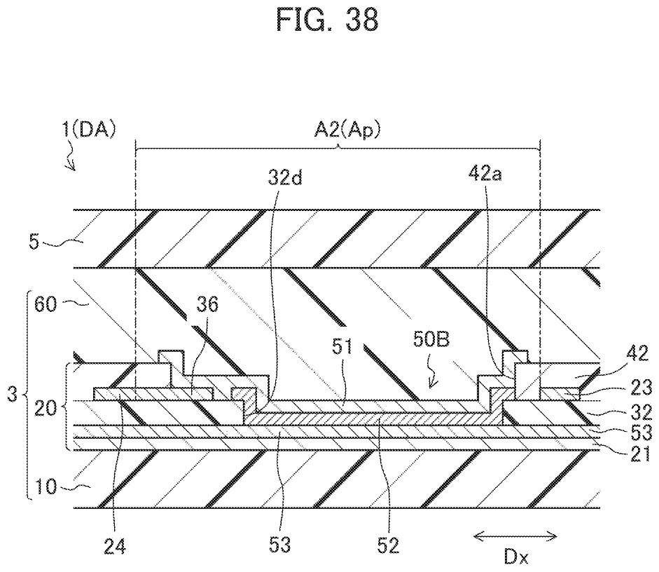

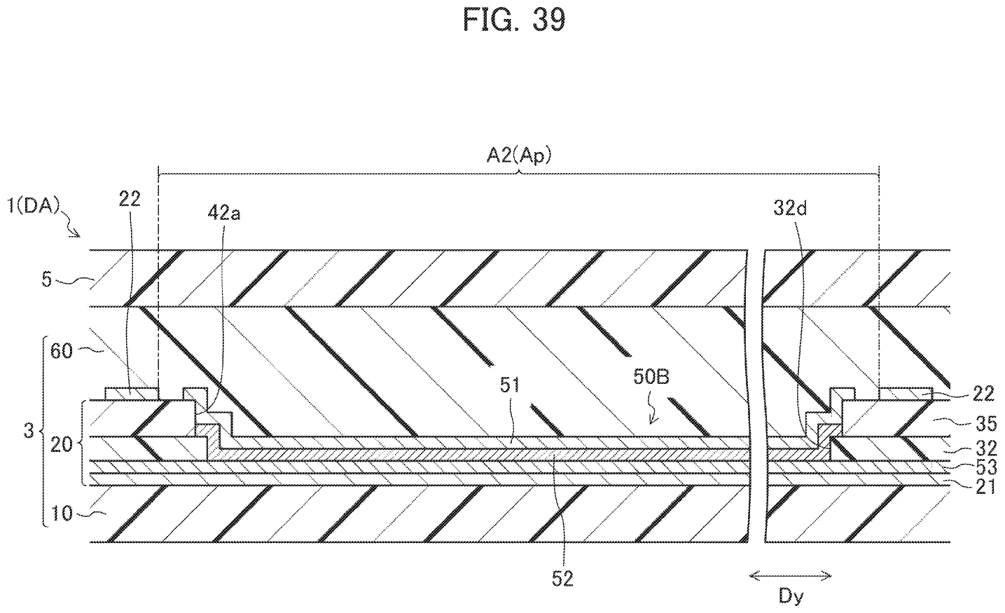

The first TFTs 30A and the second TFTs 30B of the present example are respectively structured in the same manner as the first TFTs 30A and the second TFTs 30B of the first variation example in accordance with foregoing Embodiment 1, as shown in FIGS. 36 and 37. As further shown in FIGS. 38 and 39, the common electrode 53 of the present example is also provided across the entire display area DA so as to be used commonly by the plurality of first areas A1 and the plurality of second areas A2. The common electrode 53 is disposed in a layer underlying the first insulating film 32. The common electrode 53 is provided on the base coat film 21 and covered by the first insulating film 32.

The openings 42a are provided also in portions of the second insulating film 42 that correspond to the compartmental regions Ap in which the second area A2 is specified. The plurality of openings 32d are provided in the portions of the first insulating film 32 that correspond to the first areas A1 and those portions that correspond to the second areas A2, so as to expose the common electrode 53 inside the openings 42a in the first insulating film 32. The drive electrode 36 is exposed inside the opening 42a in the second insulating film 42. The pixel electrode 51 of the present example is provided inside the opening 42a in the second insulating film 42 and connected partially overlapping the drive electrode 36.

The first organic EL element 50A has the same structure as the organic EL element 50 of the first variation example in accordance with foregoing Embodiment 1. The common electrode 53 and the pixel electrode 51 in each first area A1 face each other across the organic EL layer 52 to form the first organic EL element 50A. The organic EL layer 52 is provided also inside the openings 32d in the portions of the first insulating film 32 that correspond to the second areas A2 and disposed between the common electrode 53 and the pixel electrodes 51. The common electrode 53 and the pixel electrode 51 in each second area A2 face each other across the organic EL layer 52 to form the second organic EL element 50B.

### Second Variation Example

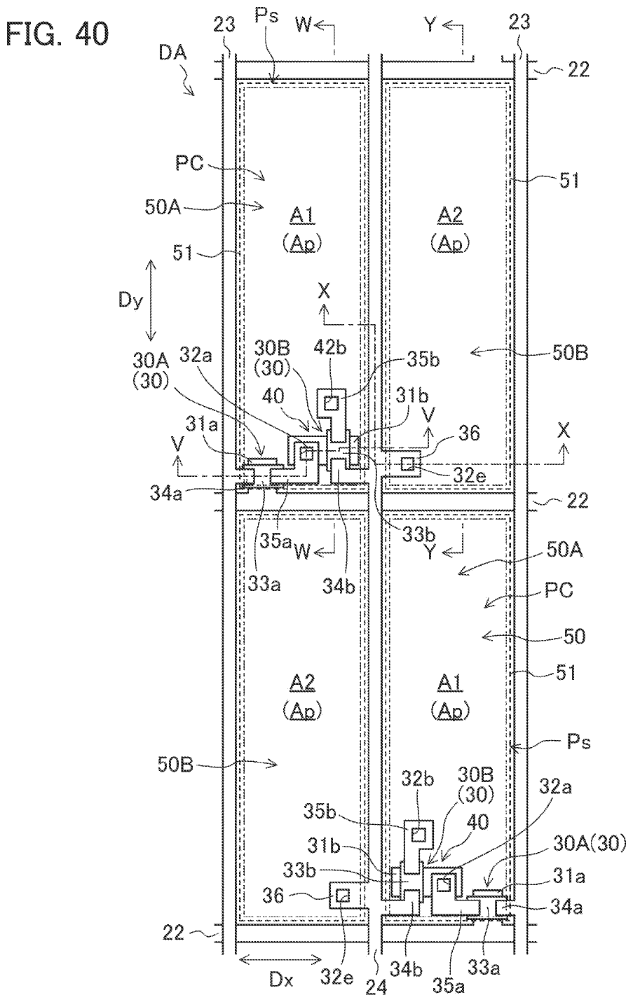

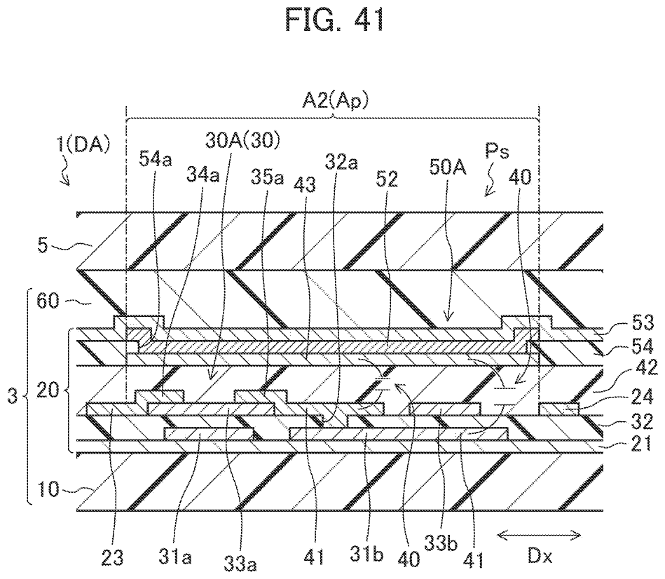

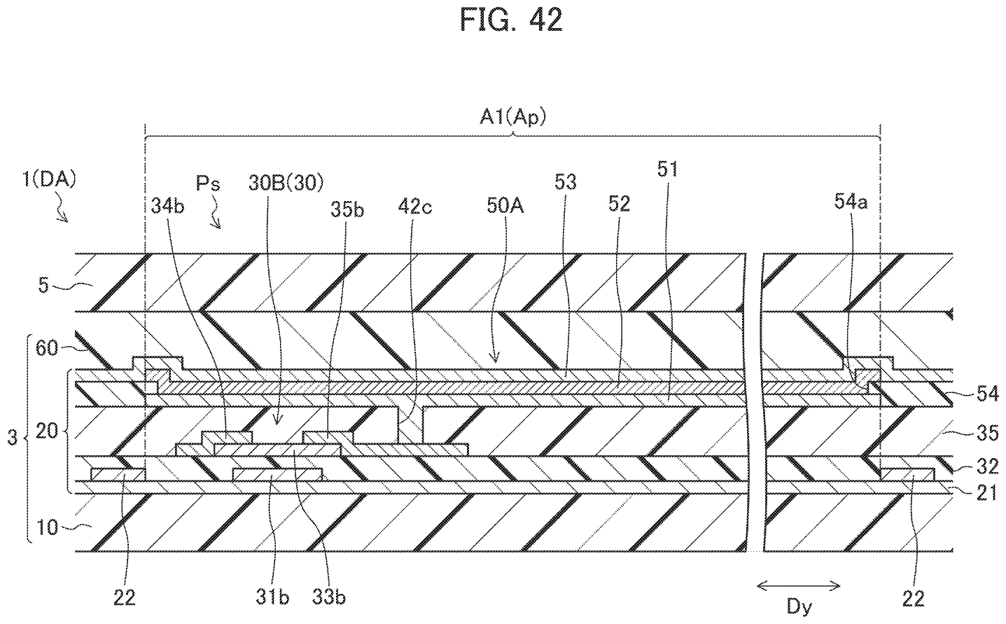

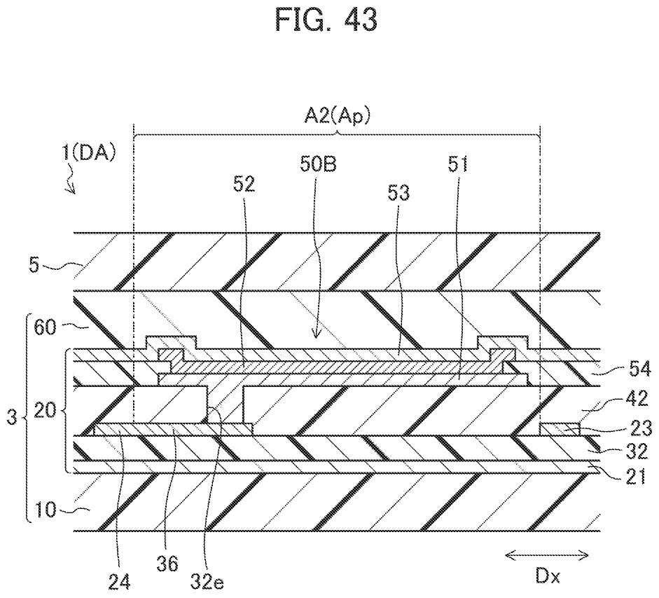

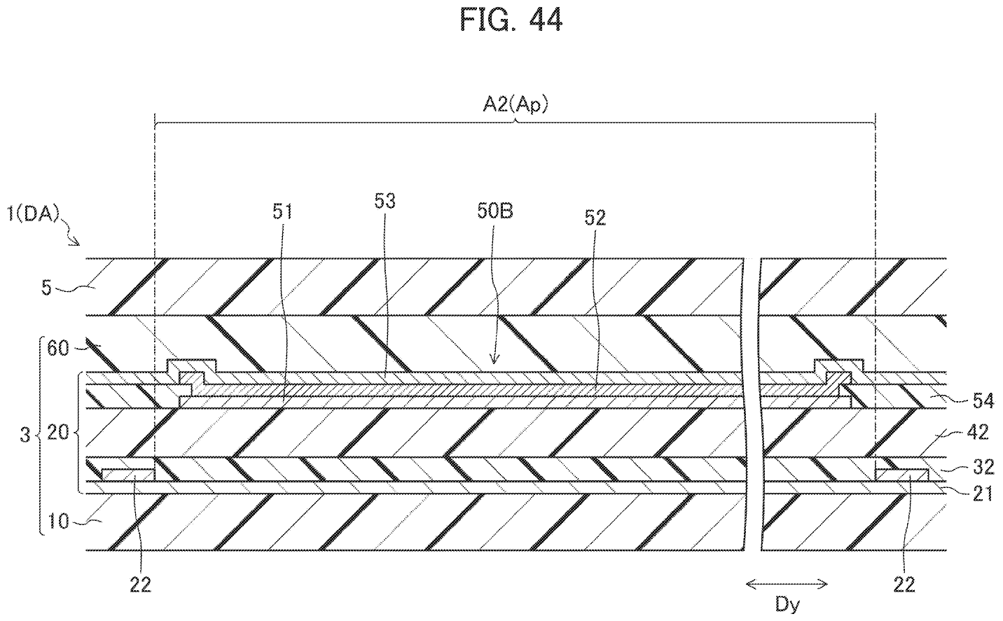

Referring to FIGS. 41 to 44, in the organic EL display device 1 of this second variation example, the first organic EL element 50A and the second organic EL element 50B are provided on the second insulating film 42 and covered by the sealing film 60. The first organic EL element 50A of the present example has the same structure as in the second variation example in accordance with foregoing Embodiment 1. As further shown in FIG. 40, the second organic EL elements 50B of the present example are provided also in those portions of the compartmental regions Ap in which the second area A2 is specified that correspond to the drive electrodes 36.

The pixel electrode 51 of each second organic EL element 50B is provided on the surface of the second insulating film 42 and compartmentalized by the edge cover 54, in the same manner as the pixel electrode 51 of each first organic EL element 50A. The pixel electrode 51 of each second organic EL element 50B is connected to an associated one of the drive electrodes 36 via a contact hole 42d formed in the second insulating film 42. The organic EL layer 52 in each second organic EL element 50B is provided on the pixel electrode 51 inside the opening 54a in the edge cover 54.

Referring to FIGS. 41 to 44, the common electrode 53 of the present example is disposed in a layer overlying the organic EL layer 52. The common electrode 53 is provided across the entire display area DA so as to be used commonly by the plurality of first areas A1 and the plurality of second areas A2. The common electrode 53 covers the organic EL layer 52 and the edge cover 54 and spreads as far as the frame area FA. The common electrode 53 is located facing the plurality of pixel electrode 51 across the organic EL layer 52.

### Third Variation Example

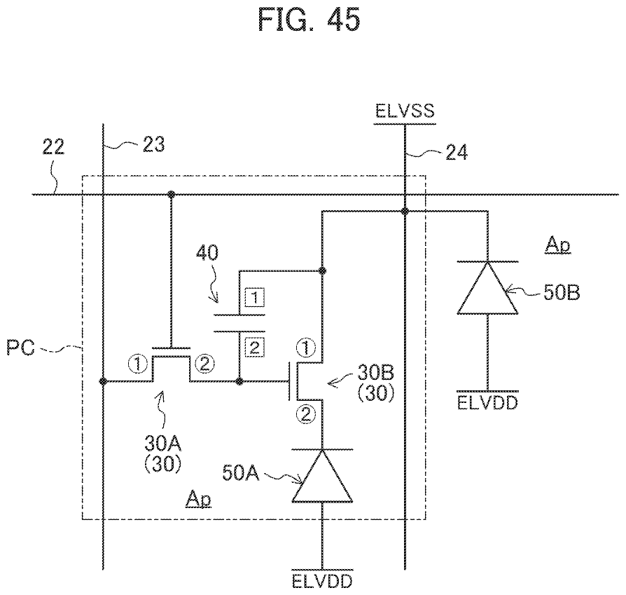

In the organic EL display device 1 of this third variation example, the pixel electrode 51 serves as a cathode, and the common electrode 53 serves as an anode. Referring to FIG. 45, the power supply line 24 is fed with a low-level power supply voltage (ELVSS) via the first frame line La. The common electrode 53 used commonly by the first organic EL element 50A and the second organic EL element 50B is fed with a high-level power supply voltage (ELVDD) via the second frame line Lb.

In the pixel circuit PC of the present example, the first capacitor electrode 41 of the capacitor 40 is connected to the power supply line 24, together with the second terminal electrode 35b of the second TFT 30B. Each organic EL layer 52 in the first organic EL element 50A and the second organic EL element 50B has a layered structure in which the organic EL layer 52 in accordance with foregoing Embodiment 1 is reversed. The organic EL layer 52 includes an electron injection layer 52e, an electron transport layer 52d, a light-emitting layer 52c, a hole transport layer 52b, and a hole injection layer 52a, all of which are provided sequentially on the pixel electrode 51.

### Embodiment 3

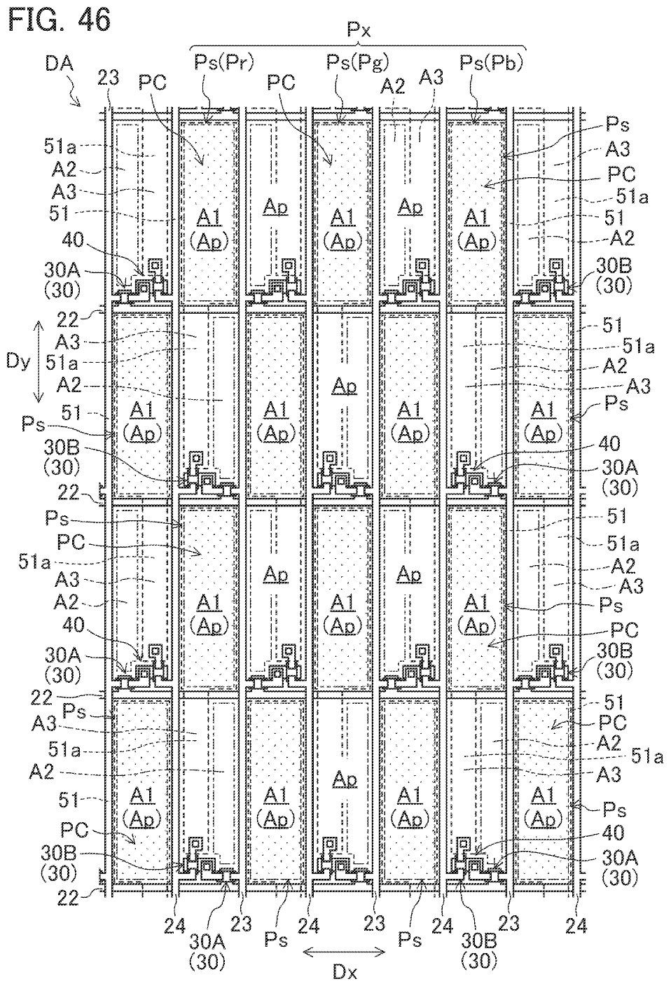

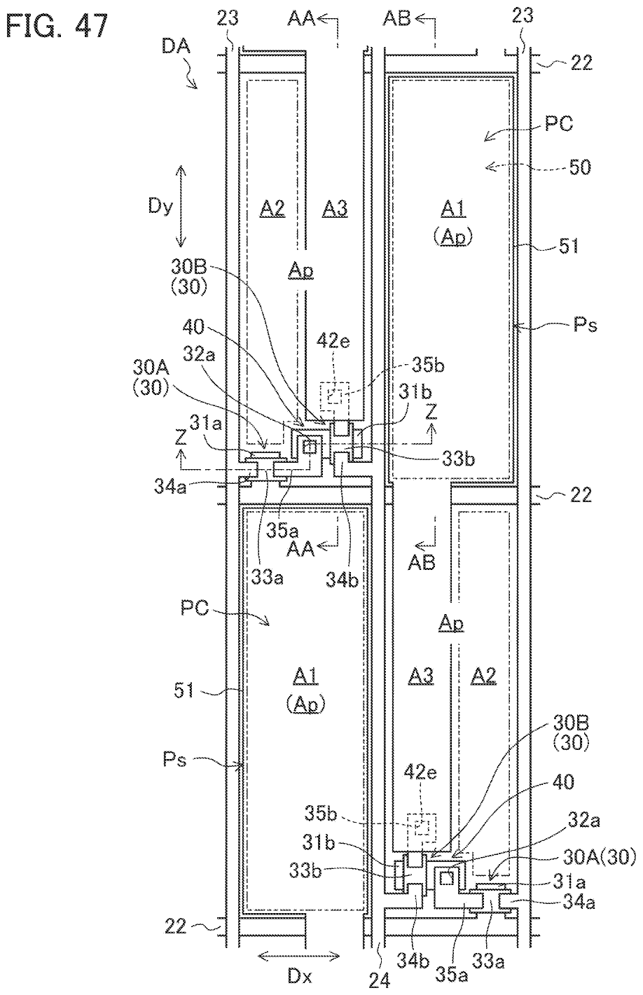

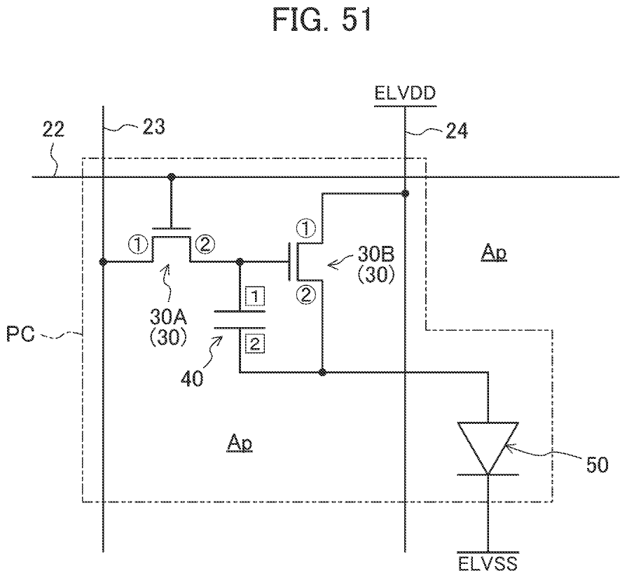

Referring to FIGS. 46 and 47, in the organic EL display device 1 of in accordance with this Embodiment 3, the pixel circuit PC is provided across two compartmental regions Ap that are adjacent to each other in the column direction Dy. As further shown in FIG. 51, in the pixel circuit PC of the present example, some of the first TFT 30A, the second TFT 30B, the capacitor 40, and the organic EL element 50 are disposed in one compartmental region Ap, and the rest in a different compartmental region Ap.

One of the two compartmental regions Ap that are adjacent to each other in the column direction Dy includes the first TFT 30A, the second TFT 30B, and the capacitor 40, but not the organic EL element 50 (except for the pixel electrode 51). The other compartmental region Ap includes the organic EL element 50, but not the first TFT 30A, the second TFT 30B, or the capacitor 40.

The compartmental region Ap in which the organic EL element 50 is provided forms the first area A1. The organic EL element 50 is provided substantially across the entire compartmental region Ap that forms the first area A1. In other words, the first area A1 is specified substantially across the entire compartmental region Ap in which the organic EL element 50 is provided. The plurality of first areas A1 are arranged in a staggered manner in the same manner as in foregoing Embodiment 1. Referring to FIG. 50, the organic EL element 50 is provided on the second insulating film 42 and covered by the sealing film 60.

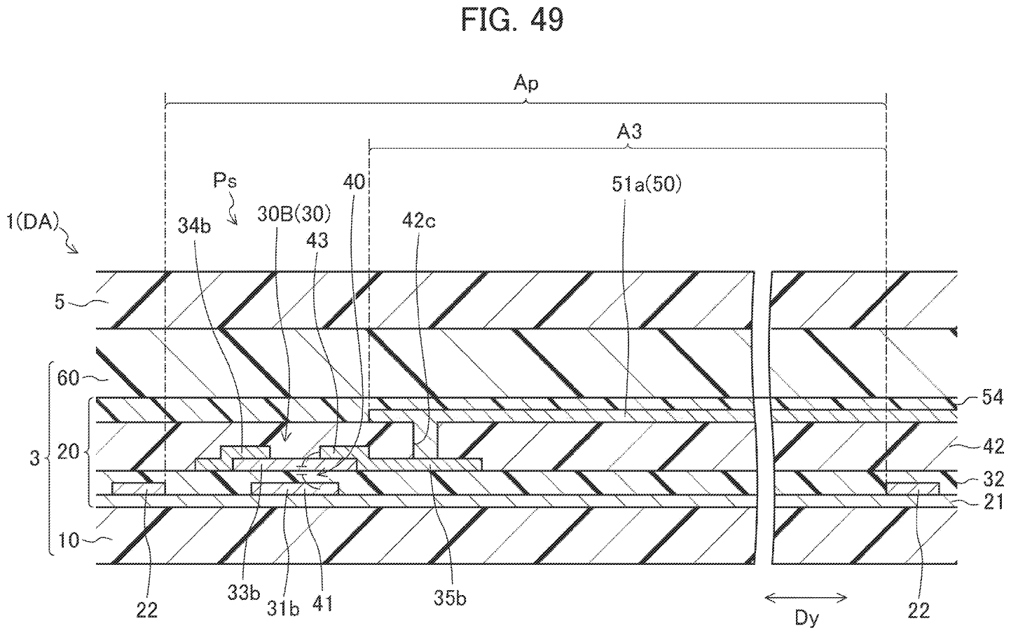

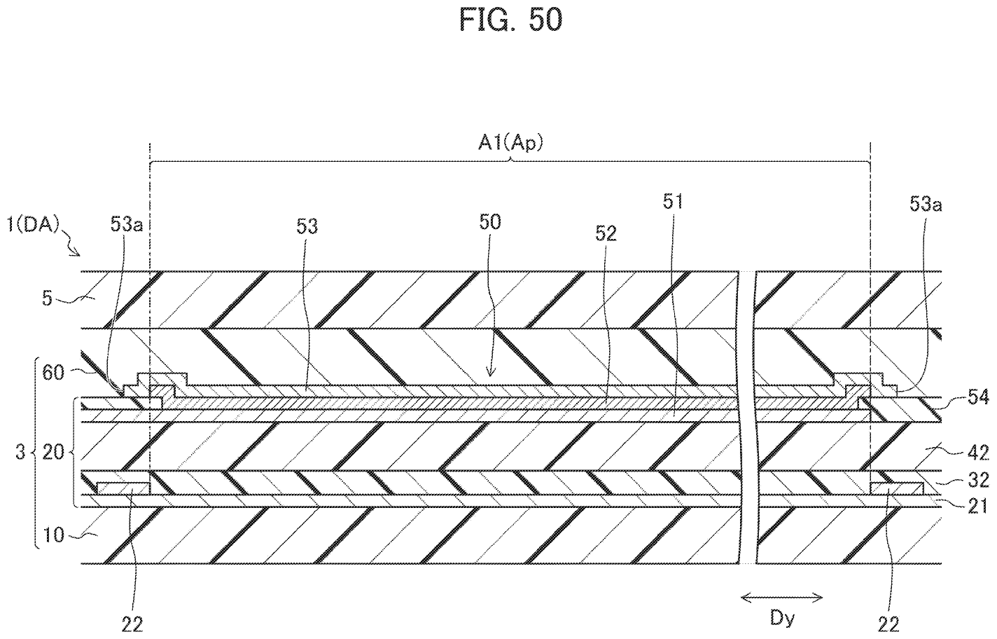

The plurality of pixel electrodes 51 are provided on the surface of the second insulating film 42. As further shown in FIG. 49, each pixel electrode 51 includes an extension 51a that extends and projects in the column direction Dy out of the compartmental region Ap in which the first area A1 is specified. The extension 51a of each pixel electrode 51 extends as far as the compartmental region Ap in which the first TFT 30A, the second TFT 30B, and the capacitor 40 are provided, the compartmental region Ap being adjacent in the column direction Dy to the compartmental region Ap in which the corresponding organic EL element 50 is provided.

The extension 51a of each pixel electrode 51 is connected to the second terminal electrode 35b of an associated one of the second TFTs 30B via the contact hole 42c formed in the second insulating film 42. As described here, each organic EL element 50 is connected to the second TFT 30B not in the compartmental region Ap in which the first area A is specified, but in the compartmental region Ap in which the second area A2 is specified. Each compartmental region Ap in which the first TFT 30A, among others, is provided forms the second area A2.

The second area A2 is specified in a portion on one of the two sides in the row direction Dx of each compartmental region Ap in which the first TFT 30A, among others, is provided. The portion on the other side in the row direction Dx of each compartmental region Ap in which the first TFT 30A, among others, is provided forms a third area A3. The third area A3 is a region where the extension 51a of the pixel electrode 51 is provided. In the third area A3, the light coming from behind is blocked by the extension 51a of the pixel electrode 51. In the present example, the first area A1 is larger in area than the second area A2.

The plurality of second areas A2 are arranged in a staggered manner so as to be located between adjacent first areas A1 in the same manner as in foregoing Embodiment 1. The first areas A1 and the second areas A2 are alternately provided in the row direction Dx and alternately provided in the column direction Dy. Specifically, in one of two rows of subpixels Ps that are adjacent to each other in the column direction Dy, the first area A1, the third area A3, and the second area A2 are repeatedly provided in the row direction Dx. In the other row of subpixels Ps, the first area A1, the second area A2, and the third area A3 are repeatedly provided in the row direction Dx.

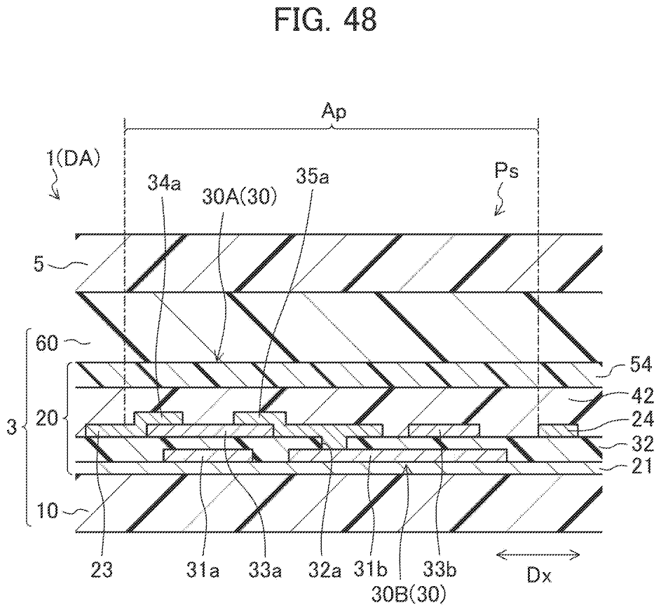

Referring to FIGS. 48 to 50, the common electrode 53 of the present example is provided in the first area A1, but not in the second area A2. In the common electrode 53, the plurality of openings 53a are arranged in a staggered manner so as to correspond to the second areas A2 in the same manner as in foregoing Embodiment 1. The common electrode 53 is provided so as to cover each organic EL layer 52. The common electrode 53 is located facing the plurality of pixel electrodes 51 via the organic EL layer 52.

### Features of Embodiment 3

In the organic EL display device 1 in accordance with this Embodiment 3, some of the first TFT 30A, the second TFT 30B, the capacitor 40, and the organic EL element 50 are disposed in one compartmental region Ap, and the rest in a different compartmental region Ap. Hence, the first area A1 can be specified so as to occupy the whole compartmental region Ap while reducing parasitic capacitance between the organic EL element 50 and, for example, the first TFT 30A and the second TFT 30B.

### First Variation Example

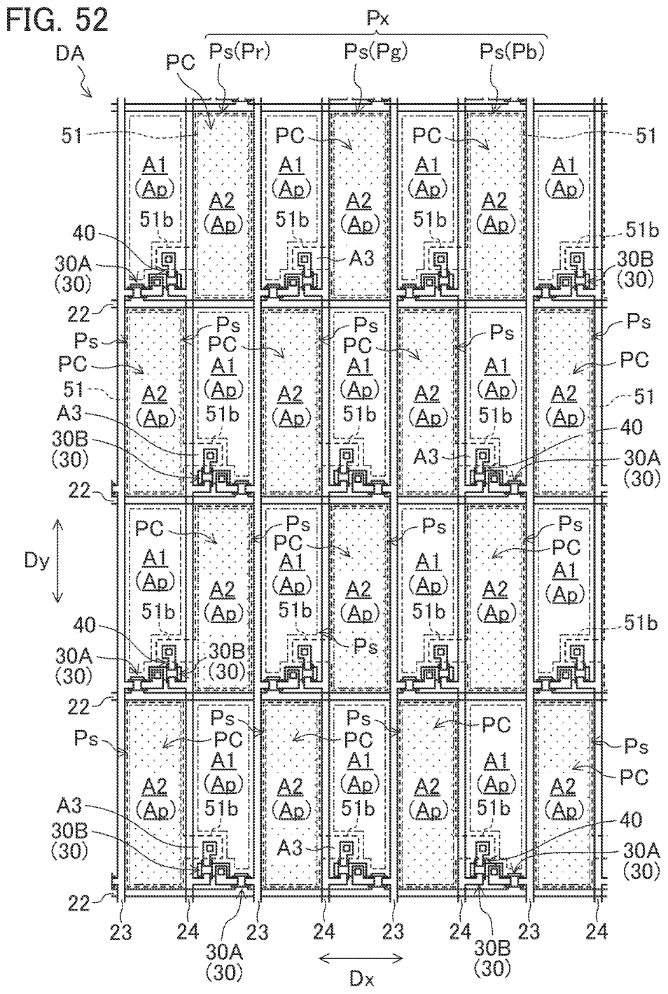

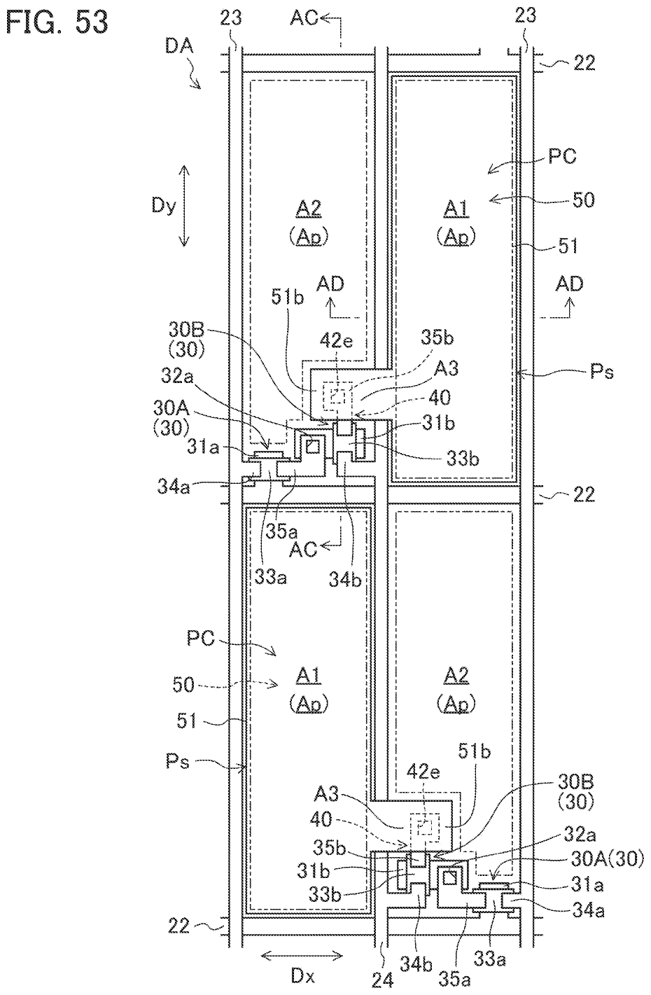

Referring to FIGS. 52 and 53, in the organic EL display device 1 of this first variation example, the pixel circuit PC is provided across two compartmental regions Ap that are adjacent to each other in the row direction Dx. In the pixel circuit PC of the present example, some of the first TFT 30A, the second TFT 30B, the capacitor 40, and the organic EL element 50 are disposed in one compartmental region Ap, and the rest in a different compartmental region Ap.

One of the two compartmental regions Ap that are adjacent to each other in the row direction Dx includes the first TFT 30A, the second TFT 30B, and the capacitor 40, but not the organic EL element 50 (except for the pixel electrode 51). The other compartmental region Ap includes the organic EL element 50, but not the first TFT 30A, the second TFT 30B, or the capacitor 40.

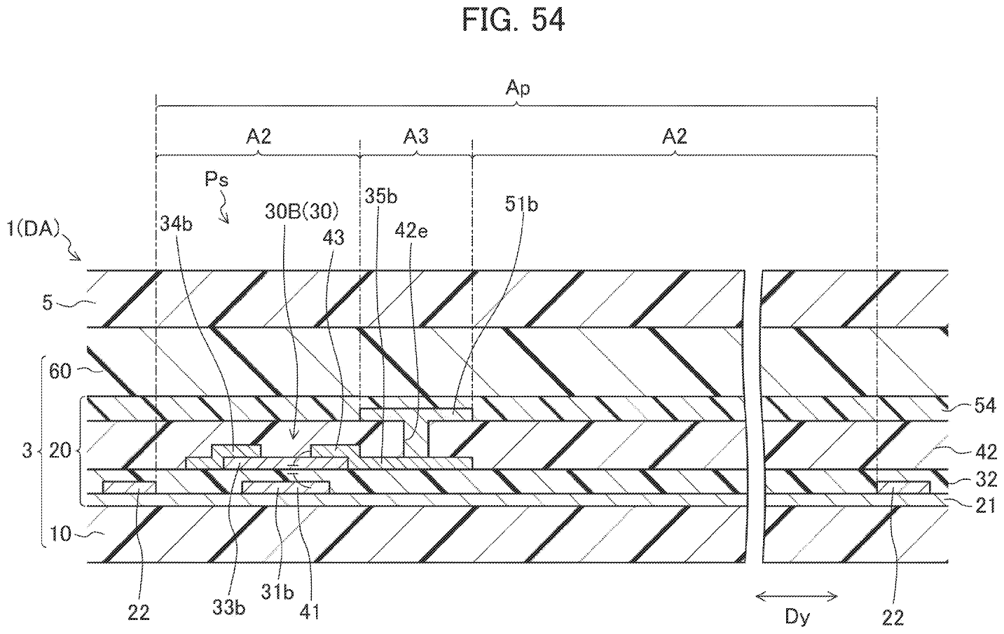

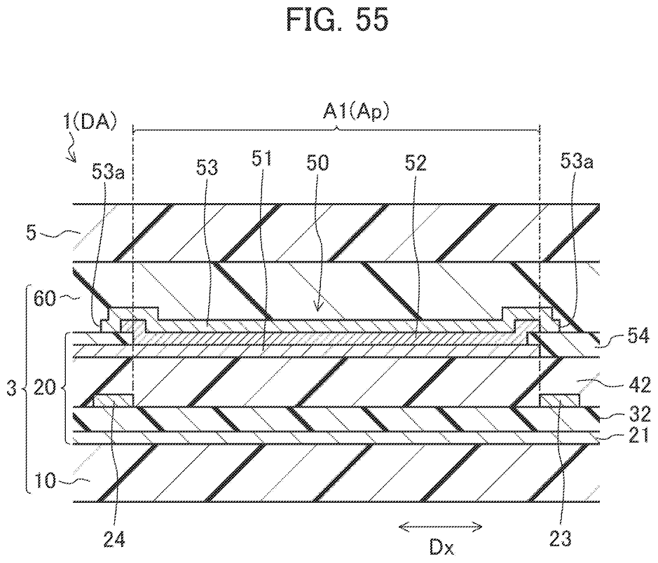

The compartmental region Ap in which the organic EL element 50 is provided forms the first area A1. The organic EL element 50 is provided substantially across the entire compartmental region Ap that forms the first area A1. In other words, the first area A1 is specified substantially across the entire compartmental region Ap in which the organic EL element 50 is provided. The plurality of first areas A1 are arranged in a staggered manner in the same manner as in foregoing Embodiment 1. As further shown in FIGS. 54 and 55, each pixel electrode 51 includes an extension 51b that extends and projects in the row direction Dx out of the compartmental region Ap in which the first area A1 is specified.

The extension 51b of each pixel electrode 51 extends as far as the compartmental region Ap in which the second area A2 is specified, the compartmental region Ap being adjacent in the row direction Dx to the compartmental region Ap in which the organic EL element 50 is provided. This extension 51b is connected to the second terminal electrode 35b of an associated one of the second TFTs 30B via a contact hole 42e formed in the second insulating film 42. As described here, each organic EL element 50 is connected to the second TFT 30B not in the compartmental region Ap in which the first area A1 is specified, but in the compartmental region Ap in which the second area A2 is specified.

The plurality of second areas A2 are arranged in a staggered manner so as to be located between adjacent first areas A1 in the same manner as in foregoing Embodiment 1. The first areas A1 and the second areas A2 are alternately provided in the row direction Dx and alternately provided in the column direction Dy. A part of each compartmental region Ap in which the second area A2 is specified forms the third area A3. The third area A3 is a region where the extension 51b of the pixel electrode 51 is provided. The first area A1 is larger in area than the second area A2 again in the present example.

### Second Variation Example

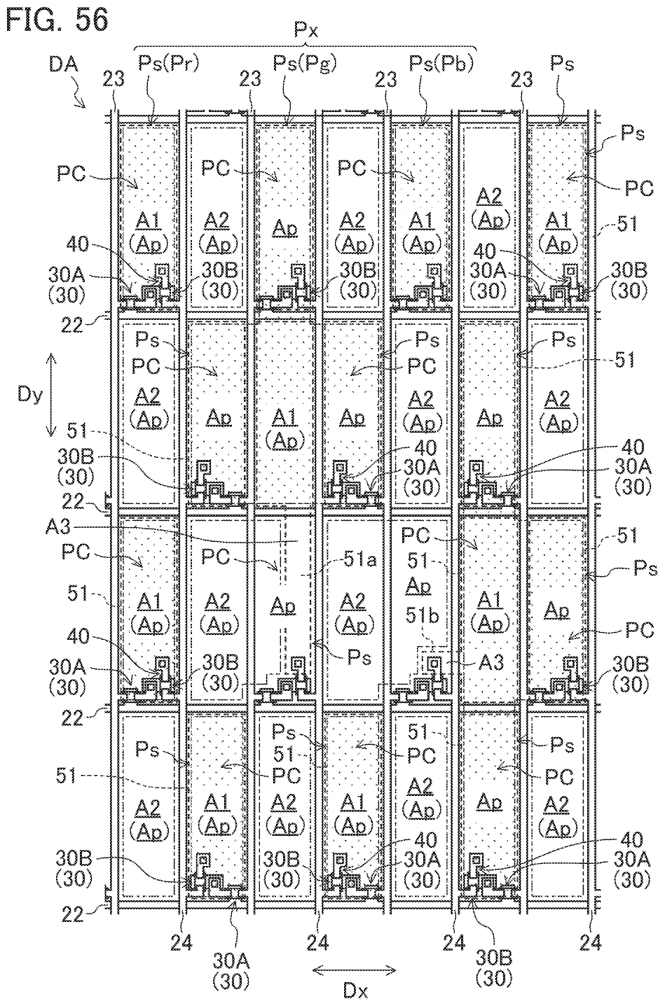

Referring to FIG. 56, in the organic EL display device 1 of this second variation example, some pixel circuits PC are provided across two compartmental regions Ap that are adjacent to each other in the column direction Dy. The first TFT 30A, the second TFT 30B, the capacitor 40, and the organic EL element 50 that form each of these pixel circuits PC are structured in the same manner as in foregoing Embodiment 3. The compartmental region Ap in which the organic EL element 50 is provided for such a pixel circuit PC forms one first area A1, in combination with the two compartmental regions Ap in which the organic EL element 50 is provided, the two compartmental regions Ap being located on either side of that compartmental region Ap in the row direction Dx.

In addition, some pixel circuits PC are provided across two compartmental regions Ap that are adjacent to each other in the row direction Dx. The first TFT 30A, the second TFT 30B, the capacitor 40, and the organic EL element 50 that form each of these pixel circuits PC are structured in the same manner as in the foregoing first variation example. The compartmental region Ap in which the organic EL element 50 is provided for such a pixel circuit PC forms one first area A1, in combination with the compartmental region Ap that is located on a side (to the right in FIG. 56) of that compartmental region Ap in the row direction Dx and in which the organic EL element 50 is provided and with the compartmental regions Ap that are located on either side of that compartmental region Ap in the column direction Dy and in which the organic EL element 50 is provided.

The organic EL display device 1 of this second variation example includes: the pixel circuits PC in each of which the first TFT 30A, the second TFT 30B, and the capacitor 40 are provided in one of the two compartmental regions Ap that are adjacent to each other in the row direction Dx, whereas the organic EL element 50 is provided in the other compartmental region Ap; and the pixel circuits PC in each of which the first TFT 30A, the second TFT 30B, and the capacitor 40 are provided in one of the two compartmental regions Ap that are adjacent to each other in the column direction Dy, whereas the organic EL element 50 is provided in the other compartmental region Ap. As described here, the arrangement of particular pixel circuits PC in an irregular pattern is advantageous in improving freedom in the arrangement of the subpixels Ps.

### Third Variation Example

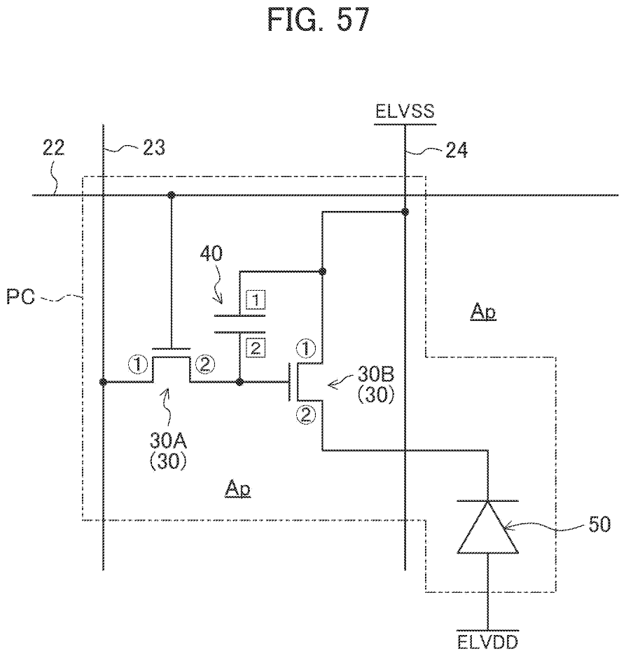

In the organic EL display device 1 of this second variation example, the pixel electrode 51 serves as a cathode, and the common electrode 53 serves as an anode. Referring to FIG. 57, the power supply line 24 is fed with a low-level power supply voltage (ELVSS) via the first frame line La. The common electrode 53 of the organic EL element 50 is fed with a high-level power supply voltage (ELVDD) via the second frame line Lb.

In the pixel circuit PC of the present example, the second capacitor electrode 43 of the capacitor 40 is connected to the power supply line 24, together with the second terminal electrode 35b of the second TFT 30B. The organic EL layer 52 of the organic EL element 50 has a layered structure in which the organic EL layer 52 in accordance with foregoing Embodiment 1 is reversed. The organic EL layer 52 includes an electron injection layer 52e, an electron transport layer 52d, a light-emitting layer 52c, a hole transport layer 52b, and a hole injection layer 52a, all of which are provided sequentially on the pixel electrode 51.

The description has so far discussed preferred embodiments as examples of the technique of the present disclosure. However, the technique of the present disclosure is not limited to these examples and is also applicable to embodiments that may include modifications, replacements, additions, and omissions in a suitable manner. One of ordinary skill in the art would appreciate that the foregoing embodiments may be further modified in various manners without departing from the scope of the technique of the present disclosure and that such modifications also fall within the scope of the technique of the present disclosure.

Foregoing Embodiments 1 to 3 have described, by way of examples, that the organic EL layer 52 is individually provided for each subpixel Sp. Alternatively, the organic EL layer 52 may be contiguously provided commonly to a plurality of subpixels Sp. In such a case, the organic EL display device 1 may include, for example, a color filter to produce shades of color in each subpixel Sp.

Foregoing Embodiments 1 to 3 have described that the pixels Px include subpixels Pr, Pg, Pb of 3 colors. Alternatively, the pixels Px may include subpixels Ps of four or more colors. In addition, the three-color subpixels Pr, Pg, Pb in each pixel Px have been described as being adjacent to each other in the row direction Dx. Alternatively, the three-color subpixels Ps in each pixel PX may be three subpixels Ps that are arranged like a Greek letter Δ or in any other pattern.

Foregoing Embodiments 1 to 3 have described that the pixel circuit PC includes two TFTs 30: the first TFT 30A and the second TFT 30B. Alternatively, the pixel circuit PC may include three or more TFTs 30. In addition, the same pixel circuit PC may be configured by swapping the direction in which the gate lines 22 extend and the direction in which the source lines 23 and the power supply lines 24 extend, so that the gate lines 22 extend in the column direction Dy and the source lines 23 and the power supply lines 24 extend in the row direction Dx.

Foregoing Embodiments 1 and 3 have described that the organic EL element 50 has a top-emission structure. Alternatively, the organic EL element 50 may have a bottom-emission structure in which the light emitted by the organic EL layer 52 is extracted through the base substrate 10 side. The organic EL element 50 may have a top- and bottom-emission structure in which the light emitted by the organic EL layer 52 is extracted both through the base substrate 10 side and through the opposite substrate 5 side. These configurations are equally applicable to the first organic EL element 50A and the second organic EL element 50B in accordance with foregoing Embodiment 2.

Foregoing Embodiments 1 to 3 have described that the organic EL layer 52 has a five-layered structure including the hole injection layer 52a, the hole transport layer 52b, the light-emitting layer 52c, the electron transport layer 52d, and the electron injection layer 52e. Alternatively, the organic EL layer 52 may have a three-layered structure including a hole injection and transport layer, a light-emitting layer, and an electron transport and injection layer or have any other layered structure.

Foregoing Embodiments 1 to 3 have described that the display device is, by way of example, the organic EL display device 1. Alternatively, the technique of the present disclosure may be applicable to, for example, display devices that have a plurality of current-driven light-emitting elements. This display device may be, for example, a display device that includes QLEDs (quantum-dot light-emitting diodes), which are light-emitting elements including a quantum-dot-containing layer.

### Industrial Applicability

As described above, the technique of the present disclosure is useful in display devices that serve as a see-through display device.

### REFERENCE SIGNS LIST

A1 First Area
A2 Second Area
Ap Compartmental Region
Dx Row Direction (First Direction)
Dy Column Direction (Second Direction)
PC Pixel Circuit
1 Organic EL Display Device (Display Device)
22 Gate Line (Third Wiring Line)
23 Source Line (First Wiring Line)
24 Power Supply Line (Second Wiring Line)
30 TFT (Active Element)
32 First Insulating Film (Insulating Film)
42 Second Insulating Film (Insulating Film)
30A First TFT (Active Element)
30B Second TFT (Active Element)
50 Organic EL Element (Light-emitting Element)
50A First Organic EL Element (Light-emitting Element)
50B Second Organic EL Element (Light-emitting Element)

1. A display device comprising:
a plurality of light-emitting elements arranged both in a first direction and in a second direction, the first direction and the second direction being orthogonal to each other; and
a plurality of active elements configured to respectively control emission of light by the plurality of light-emitting elements,
the display device displaying an image by controlling the emission of light by the plurality of light-emitting elements through operation of the plurality of active elements individually for the plurality of light-emitting elements arranged in the first direction or individually for the plurality of light-emitting elements arranged in the second direction, wherein
a display area where an image is displayed includes:
a plurality of first areas capable of emitting light owing to the plurality of light-emitting elements; and
a plurality of second areas capable of transmitting light that comes from behind, and the plurality of first areas and the plurality of second areas are alternately provided in the first direction and in the second direction.

2. The display device according to claim 1, wherein
the plurality of light-emitting elements and the plurality of active elements that control the plurality of light-emitting elements form a plurality of pixel circuits configured to supply a drive current to the plurality of light-emitting elements,
a plurality of first wiring lines and a plurality of second wiring lines both connected to the plurality of pixel circuits arranged in the second direction are provided in the display area, and
the plurality of first wiring lines and the plurality of second wiring lines respectively extend in the second direction and are alternately provided in the first direction, sandwiching the plurality of pixel circuits.

3. The display device according to claim 2, wherein the plurality of first wiring lines and the plurality of second wiring lines are made of a same material and provided in a same layer.

4. The display device according to claim 2, wherein
a plurality of third wiring lines connected to the plurality of pixel circuits arranged in the first direction are provided in the display area so as to extend in the first direction, and
the plurality of first areas and the plurality of second areas are respectively specified in compartmental regions compartmentalized by the plurality of first wiring lines, the plurality of second wiring lines, and the plurality of third wiring lines.

5. The display device according to claim 4, wherein the plurality of light-emitting elements overlap the plurality of first wiring lines, the plurality of second wiring lines, or the plurality of third wiring lines via an insulating film and are provided across two adjacent compartmental regions of the compartmental regions in which the plurality of first areas and the plurality of second areas are specified.

6. The display device according to claim 5, wherein the plurality of light-emitting elements are connected to the plurality of active elements in the compartmental regions in which the plurality of second areas are specified.

7. The display device according to claim 4, wherein the plurality of light-emitting elements and the plurality of active elements are respectively provided in the compartmental regions in which the plurality of first areas are specified, not in the compartmental regions in which the plurality of second areas are specified.

8. The display device according to claim 1, wherein
the plurality of light-emitting elements are provided respectively in the plurality of first areas and the plurality of second areas, and
the plurality of light-emitting elements in the plurality of second areas are transmissive to light.

9. The display device according to claim 1, wherein the plurality of first areas and the plurality of second areas are arranged in a checkered pattern.

10. The display device according to claim 1, wherein the plurality of first areas are larger in area than the plurality of second areas.

11. The display device according to claim 1, wherein the plurality of second areas are larger in area than the plurality of first areas.

12. The display device according to claim 1, wherein the plurality of light-emitting elements are organic electroluminescence elements.
